(19) United States
(12) Patent Application Publication
(10) Pub. No.: US 2019/0109581 A1
(43) Pub. Date: Apr. 11, 2019

(54) ADAPTIVE FILTER METHOD, SYSTEM AND APPARATUS

(71) Applicant: King Fahd University of Petroleum and Minerals, Dhahran (SA)

(72) Inventors: Ahmad KHALIFI, Dhahran (SA); Azzedine Mohamed Ali ZERGUINE, Dhahran (SA)

(73) Assignee: King Fahd University of Petroleum and Minerals, Dhahran (SA)

(21) Appl. No.: 16/003,980

(22) Filed: Jun. 8, 2018

Related U.S. Application Data
(60) Provisional application No. 62/568,552, filed on Oct. 5, 2017.

(51) Int. Cl. H03H 21/00; G06F 7/548; G06F 17/11; G06F 17/16

(52) U.S. Cl. CPC H03H 21/0043; G06F 7/548; H03H 2021/0078; G06F 17/16; H03H 2021/0045; G06F 17/11

(57) ABSTRACT

The present disclosure relates to adaptive filtering optimization methods based on a hyperbolic sine cost function. While the adaptive filtering optimization methods belong to the variable step-size class, however, the present disclosure describes a new approach requiring tuning of only one parameter. The present disclosure is further related to a family of higher order hyperbolic sine cost functions.

### CROSS-REFERENCE TO RELATED APPLICATIONS

The present application claims priority to U.S. Provisional Application No. 62/568,552, filed Oct. 5, 2017, which is hereby incorporated by reference in its entirety for all purposes.

### STATEMENT REGARDING PRIOR DISCLOSURE BY THE INVENTORS

Aspects of this technology are described in an article “Adaptive Algorithm Based on a New Hyperbolic Sine Cost Function”, published at the Asilomar Conference on Signals, Systems and Computers, on Oct. 29 2017, which is incorporated herein by reference in its entirety.

### BACKGROUND

### Field of the Disclosure

The present disclosure relates to a method for adaptive filtering, an adaptive filter, a computer device and/or system programmed with instructions for adaptive filtering and generally a family of adaptive filtering optimization methods employing a hyperbolic since-based cost function.

### Description of the Related Art

An adaptive filter is a computational device that attempts to model the relationship between two signals in real time in an iterative manner. Adaptive filters are often realized either as a set of program instructions or as a set of logic operations. However, the fundamental operation of the adaptive filter can be characterized independent of a hardware implementation, and therefore, mathematical forms of adaptive filters become the focus of new developments in the field. An adaptive filter is defined by four aspects, including (1) the signals being processed by the filter, (2) the structure that defines how the output signal of the filter is computed from its input signal, (3) the parameters within this structure that can be iteratively changed to alter the filter's input-output relationship, and (4) the adaptive algorithm that describes how the parameters are adjusted from one time instant to the next. In choosing a particular adaptive filter structure, one specifies the number and type of parameters that can be adjusted. The adaptive algorithm used to update the parameter values of the system can take on a myriad of forms and is often derived as a form of optimization procedure that minimizes an error criterion that is useful for the task at hand. Often, a least-mean-square optimization method is employed to adjust the coefficients of an adaptive filter. In adjusting, or updating, the coefficients of the adaptive filter over time, an optimization method hopes to create an output that is a better and better match to a desired response signal, such that the error criterion is reduced.

Adaptive filters, including the least-mean-square optimization method, have witnessed an increased demand in various emerging applications. While accessible, adaptive filters are often described by a series of trade-offs. For example, in order to achieve fast convergence, a large step-size compared to a reciprocal of the input signal power is required, resulting in high steady-state error. Conversely, reducing steady-state error requires decreasing the step-size, an adjustment that slows convergence and impedes the utility of adaptive filters in certain applications. Moreover, large step-sizes are appropriate in some instances while small step-sizes are appropriate in others. A variety of approaches to this problem have been introduced, however, an optimal solution to the error function has yet to be developed.

The foregoing “Background” description is for the purpose of generally presenting the context of the disclosure. Work of the inventors, to the extent it is described in this background section, as well as aspects of the description which may not otherwise qualify as prior art at the time of filing, are neither expressly or impliedly admitted as prior art against the present invention.

### SUMMARY

The present disclosure relates to a method for adaptive filtering, the method comprising receiving, via processing circuitry, an input signal, generating, via the processing circuitry, an initial output signal based upon an initial set of one or more coefficients, determining, via the processing circuitry, an error signal based upon the difference between the initial output signal and a desired response signal, calculating, via the processing circuitry, a solution to a function based upon the error signal, and generating, via the processing circuitry, a subsequent output signal based upon a subsequent set of one or more coefficients, wherein the subsequent set of one or more coefficients is determined by adjusting the initial set of one or more coefficients based upon the calculation of the solution to the function, wherein the initial set of one or more coefficients is adjusted in order to minimize the function, wherein the function is a hyperbolic sine-based function.

According to an embodiment of the present disclosure, the present disclosure further relates to a device for adaptive filtering, comprising a processing circuitry configured to receive an input signal, generate an initial output signal based upon an initial set of one or more coefficients, determine an error signal based upon the difference between the initial output signal and a desired response signal, calculate a solution to a function based upon the error signal, and generate a subsequent output signal based upon a subsequent set of one or more coefficients, wherein the subsequent set of one or more coefficients is determined by adjusting the initial set of one or more coefficients based upon the calculation of the solution to the function, wherein the initial set of one or more coefficients is adjusted in order to minimize the function, wherein the function is a hyperbolic sine-based function.

According to an embodiment of the present disclosure, the present disclosure further relates to a non-transitory computer-readable medium comprising a set of instructions, which, when executed by a processing circuitry, cause the processing circuitry to perform a method, comprising receiving, via processing circuitry, an input signal, generating, via the processing circuitry, an initial output signal based upon an initial set of one or more coefficients, determining, via the processing circuitry, an error signal based upon the difference between the initial output signal and a desired response signal, calculating, via the processing circuitry, a solution to a function based upon the error signal, and generating, via the processing circuitry, a subsequent output signal based upon a subsequent set of one or more coefficients, wherein the subsequent set of one or more coefficients is determined by adjusting the initial set of one or more coefficients based upon the calculation of the solution to the function, wherein the initial set of one or more coefficients is adjusted in order to minimize the function, wherein the function is a hyperbolic sine-based function.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a schematic of a system identification block diagram, according to an exemplary embodiment of the present disclosure;

FIG. 2 is a graphical representation of an Excess Mean Square Error versus a tuning parameter, according to an exemplary embodiment of the present disclosure;

FIG. 3 is a graphical representation of adaptive curves for different tuning parameter values, according to an exemplary embodiment of the present disclosure;

FIG. 4 is a generalized schematic of a system identification block diagram;

FIG. 5 is a graphical representation of adaptive curves of an optimization method of the present disclosure and the Ang method for a white Gaussian input signal and SNR=20 dB, according to an exemplary embodiment of the present disclosure;

FIG. 6 is a graphical representation of adaptive curves of an optimization method of the present disclosure and a modified variable step-size method for a white Gaussian input signal and SNR=30 dB, according to an exemplary embodiment of the present disclosure;

FIG. 7 is a graphical representation of step-size values at a sudden change point for SNR=30 dB, according to an exemplary embodiment of the present disclosure;

FIG. 8 is a graphical representation of adaptive curves of an optimization method of the present disclosure and a fast variable step-size least-mean-square method for white Gaussian input signal and SNR=30 dB, according to an exemplary embodiment of the present disclosure;

FIG. 9 is a graphical representation of adaptive curves of an optimization method of the present disclosure and an exponentiated convex variable step-size method for white Gaussian input signal and SNR=30 dB, according to an exemplary embodiment of the present disclosure;

FIG. 10 is a graphical representation of adaptive curves of an optimization method of the present disclosure and a least-mean-fourth optimization method for sub-Gaussian noise, a bipolar input signal and SNR=10 dB, according to an exemplary embodiment of the present disclosure;

FIG. 11 is a graphical representation of adaptive curves of an optimization method of the present disclosure and an exponential-error least-mean-fourth method for sub-Gaussian noise, a bipolar input signal, SNR=10 dB and exponential-error least-mean-fourth k=0.14, according to an exemplary embodiment of the present disclosure;

FIG. 12 is a graphical representation of adaptive curves of an optimization method of the present disclosure and an exponential-error least-mean-fourth method for sub-Gaussian noise, a bipolar input signal, SNR=10 dB and exponential-error least-mean-fourth k=0.009, according to an exemplary embodiment of the present disclosure;

FIG. 13 is a graphical representation of adaptive curves of an optimization method of the present disclosure and a least-mean-square-least-mean-fourth method for sub-Gaussian noise, a white-Gaussian input signal, and SNR=10 dB, according to an exemplary embodiment of the present disclosure;

FIG. 14 is a graphical representation of adaptive curves of an optimization method of the present disclosure and other counterpart optimization methods for sub-Gaussian noise, a bipolar input signal and SNR =10 dB, according to an exemplary embodiment of the present disclosure;

FIG. 15 is a graphical representation of adaptive curves of an optimization method of the present disclosure under different noise distributions, according to an exemplary embodiment of the present disclosure;

FIG. 16 is a flowchart of a method employing an adaptive filter, according to an exemplary embodiment of the present disclosure; and

FIG. 17 is a hardware description of a device employing an optimization method of the present disclosure, according to an exemplary embodiment of the present disclosure.

### DETAILED DESCRIPTION

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). Reference throughout this document to “one embodiment”, “certain embodiments”, “an embodiment”, “an implementation”, “an example” or similar terms means that a particular feature, structure, or characteristic described in connection with the embodiment is included in at least one embodiment of the present disclosure. Thus, the appearances of such phrases or in various places throughout this specification are not necessarily all referring to the same embodiment. Furthermore, the particular features, structures, or characteristics may be combined in any suitable manner in one or more embodiments without limitation.

Because of their mathematical tractability and convenient analysis, most gradient optimization methods are quadratic-based cost functions and referred to as linear-based or second order-statistics (SOS) cost functions. Least-mean-square (LMS) and normalized-least-mean-square (NLMS) are members of this class of optimization methods. Higher order-statistics (HOS) cost functions, stemming from a higher order power of adaptation error, and of which least-mean-fourth (LMF) and mixed-norm are examples, are another class of adaptive filters. HOS optimization methods, while demonstrating superior convergence speed compared with SOS optimization methods, have a higher misadjustment level when the noise is Gaussian. This is due, in part, to the steeper error surface of the HOS optimization method, allowing faster convergence while severely penalizing high deviations from the optimal solution. Recently, to improve the speed of convergence of SOS optimization methods, and to maintain a sufficient level of convergence, a new class of stochastic gradient optimization methods has been developed wherein the cost function has an exponential dependence on adaptation error. These optimization methods have a steeper surface than the quadratic cost function and can be seen as a linear combination of all the even moments. This type of optimization method outperforms LMS optimization methods with respect to convergence speed, offering increased robustness against an impulsive noise environment.

Mixed-norm optimization methods employ different error norms in order to achieve improved convergence performance. While this combination of different norms delivers an extra degree of freedom, this approach requires an optimization mixture between norms based on prior information of the input signal and noise statistics.

In the present disclosure, a new cost function, the least-hyperbolic-sine, is described. Least-hyperbolic-sine non-linearly adapts uses the error square as a driving argument. Accordingly, a stochastic gradient based optimization method, a hyperbolic sine error squared (HSS) optimization method, is described. HSS is classified as a variable step-size optimization method, with improvements in speed of convergence, adaptation to sudden changes, computational costs, and number of tuning parameters. Additionally, a derivation of the HSS optimization method is provided with supporting analysis to determine the required conditions for convergence, the excess mean steady-state error (EMSE), and the optimal solution with respect to the least-hyperbolic-sine cost function.

The following notations are used below: x denotes a column vector, x is a scalar, (.)^{T} is the transpose operator, E[.] is the mathematical expectation, and Tr[.] is the trace operator.

### I. Optimization Method Formulation

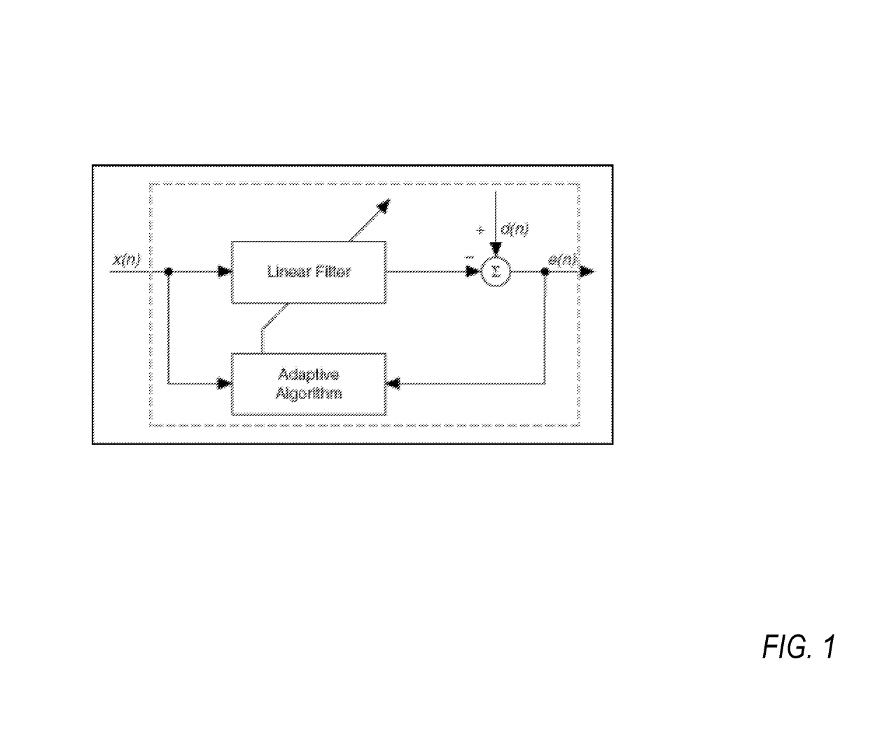

The considered optimization method formulation is developed with reference to application in a system identification scheme illustrated in FIG. 1. In FIG. 1, the “adaptive algorithm” works toward minimizing the hyperbolic sine cost function of the error squared. The instantaneous error, e(k), is defined as

e(k)=d(k)−x^{T}(k)w(k−1) (1)

where the desired signal, d(k), is defined as

d(k)=x^{T}(k)w^{o}+v(k) (2)

v(k) is a zero-mean independent random variable, and w^{o} is the optimal time-varying filter coefficients. Additionally, w=[w₀,w₁, . . . ,w_{M-1}]^{T} describes the set of filter coefficients, M is the filter length, (.)^{T} is the transpose operator, and x(k)=[x(k),x(k−1), . . . ,x(k−M+1)] is the input signal vector.

According to an embodiment of the present disclosure, the cost function is a hyperbolic sine with an error square argument, defined as

J(k)=sin h(e²(k)) (3)

The cost function is a convex and unimodal function. Its gradient with respect to the filter coefficient yields

Δ_{W}J(k)=−2e(k)cos h(e²(k))x^{T}(k) (4)

where x(k) is the regression vector. To improve the convergence speed, one can introduce a scale parameter A, where A>0, to scale the squared error in the argument of the hyperbolic sine. The resulting, modified cost function will be

$$J ( k ) = \frac{1}{A} sinh ( {Ae}^{2} ( k ) ) \qquad ( 5 )$$

Accordingly, the gradient with the new cost function will be

Δ_{w}J(k)=−2e(k)cos h(Ae²(k))x^{T}(k) (6)

Hence, the stochastic recursive form of the coefficients estimate is given as

w(k+1)=w(k)+2 μe(k)cos h(Ae²(k))x(k) (7)

It is observed that the hyperbolic cosine scales up the step-size in cases of high instantaneous error, resulting in rapid convergence. This may, however, lead to optimization method instability. In order to utilize the large gradient property while maintaining a bounded gradient, thus preserving optimization method stability, a selecting function can be used such that

$$w ( k + 1 ) = w ( k ) + 2 {μ}_{min} min [ cosh ( {Ae}^{2} ( k ) ) , \frac{{μ}_{max}}{{μ}_{min}} ] e ( k ) x ( k ) \qquad ( 8 )$$

where μₘₐₓ and μₘᵢₙ are the upper and lower bounds of μ, respectively.

### II. Generic Upper Bound of μ

According to an embodiment of the present disclosure, the upper bound of the step-size, μₘₐₓ, is a generic value rather than a fixed number. μₘₐₓ can be evaluated at each iteration as follows:

$${μ}_{max} = \frac{1}{Tr [ {R}_{x} ] + ϵ} \qquad ( 9 )$$

where ϵ«1 is used to avoid the case when Tr[Rₓ] approaches zero, hence pushing the denominator to a value of zero. By using this generic value, stability of the optimization method is guaranteed and convergence speed is improved. This can be confirmed through experimental validation, whereby a simulation is performed comparing a fixed maximum step-size with a generic maximum step-size. A generic value allows the optimization method to adapt to abrupt changes in signal power.

### III. An Optimal Solution

In evaluating the optimization method, according to an embodiment of the present disclosure, it should be verified that the behavior of the optimization method is controllable. To this end, an optimal solution is found based on the gradient of the hyperbolic sine cost function, as follows:

Δ_{w}J(k)=−2e(k)cos h(Ae²(k))x^{T}(k)=0 (10)

To express the equation in terms of the optimal tap weights w^{o}, and substituting for the e(k) from (1), the following is derived:

x(k)d(k)cos h(Ae²(k))=x(k)x^{T}w^{o} cos h(Ae²(k)) (11)

Then, taking the mathematical expectation of both sides leads to

E[x(k)d(k)cos h(Ae²(k))]=E[x(k)x^{T}(k)w^{o} cos h(Ae²(k))] (12)

Substituting a Taylor series expansion of the cos h function in (12) yields

$${P}_{xd} + {\sum }_{n = 1}^{∞} \frac{1}{( 2 n ) !} E [ x ( k ) d ( k ) {e ( k )}^{4 n} ] = {R}_{x} {w}^{0} + {\sum }_{n = 1}^{∞} \frac{1}{( 2 n ) !} E [ x ( k ) {x}^{T} ( k ) {e ( k )}^{4 n} ] {w}^{0} \qquad ( 13 )$$

where Rₓ=E[x(k)x^{T}(k)] is the auto-correlation matrix of the input signal x(k) and P_{xd}=E[x(k)d(k)] is the cross-correlation between the input signal x(k) and the desired signal d(k).

Assuming both the input vector sequence {x(k)} and the error signal sequence {e(k)} to be asymptotically uncorrelated, E[x(k)x^{T}(k)e(k)⁴ⁿ]=RₓE[e(k)⁴ⁿ]. Moreover, since the error signal is small at the steady-state scenario, the terms that include higher order powers of the error e(k) can be neglected. Hence, these situations result in an expression for the optimal tap weight given as

w^{o}=Rₓ⁻¹P_{xd} (14)

Therefore, the optimal solution, similar to the LMS optimization method, is the Wiener solution. Upon close investigation of the gradient component of (8), this similarity is observable. In fact, when the error signal e(k) is very small, for instance, at steady-state, the hyperbolic cosine can be approximated around the origin as cosh (e(k)²)≈1, hence the cost function is, effectively, a match with the quadratic cost function, which is the LMS optimization method in the standard form.

### IV. Steady-State Analysis

In performing a steady-state analysis, an analytical expression for the EMSE must be derived. This approach is understood in the art, as evidenced in “Fundamentals of Adaptive Filtering”, by Sayed, published in 2003 and “A variable step size LMS algorithm”, by Kwong and Johnston, published in IEEE Transactions on Signal Processing, vol. 40, no. 7, pp. 1633-1642, incorporated by reference herein in their entirety. In addition to the wide sense stationary channel model assumption, the following standard assumptions are introduced:
A1. There exist a vector w^{o} such that d(k)=w^{T}(k)w^{o}+v(k)
A2. The additive noise sequence {v(k)} is an i.i.d. with variance σᵥ²=E[(v(k))²]
A3. The sequence v(i) is independent of the input vector x(j) for all i, j.
A4. The initial condition w₋₁ is independent of all {d(j), x(j), v(j)}
A5. The input signal auto-correlation matrix Rₓ=E[x(k)x^{T}(k)]>0
A6. The random variables {d(k), x(k), v(k)} are centralized with zero means

According to the energy conservation framework, the steady-state EMSE is given by S is given by

$$S = \frac{μ {N}_{s}}{2 {D}_{s}} Tr [ {R}_{x} ] \qquad ( 15 )$$

where Tr[Rₓ] is the trace of the auto-correlation matrix of the input signal. N_{S} is defined as

N_{S}=E[f²(e(k))] (16)
and D_{S} is given by

$${D}_{s} = \frac{E [ {e}_{a} ( k ) \cdot f ( e ( k ) ) ]}{E [ {e}_{a}^{2} ( k ) ]} \qquad ( 17 )$$

where eₐ(k) is the apriori error defined as

eₐ(k)=[w^{o}−w(k)]^{T}x(k) (18)

f(e), at the steady-state zone, is defined from (8) as

$$w ( k + 1 ) = w ( k ) + \begin{matrix}2 {μ}_{min} cosh & ( {Ae}^{2} ( k ) ) e ( k ) \\ \underbrace{μ} & \underbrace{f ( e )}\end{matrix} x ( k ) \qquad ( 19 )$$

Accordingly, N_{S} becomes

N_{S}=E[e²(k)cos h²(Ae²(k))] (20)

For brevity, and owing to the steady-state analysis, the time index k is dropped. The estimation error e can be represented in terms of the apriori error and the noise signal as (e=eₐ+v). Accordingly, (20) becomes

N_{S}=E[eₐ² cos h²(Ae²)]+σᵥ²E[cos h²(Ae²)] (21)
where σᵥ² is the variance of the noise. By applying the Cauchy-Schwartz inequality, (21) is further simplified as

N_{S}≤\sqrt{E[eₐ⁴]·E[cos h⁴(Ae²)]}+σᵥ²E[cos h²(Ae²)] (22)

Furthermore, assuming a priori error to be zero-mean Gaussian, Jensen's inequality can be applied to solve the expectation for the hyperbolic cosine function. Thus, N_{S} can be written in closed form as:

$$\begin{matrix}{N}_{s} \leq [ \sqrt{3} E [ {e}_{a}^{2} ] + {σ}_{v}^{2} ] \cdot {cosh}^{2} ( AE [ {e}_{a}^{2} + {σ}_{v}^{2} ] ) & ( 23 ) \\ {N}_{s} \leq [ \sqrt{3} S + {σ}_{v}^{2} ] \cdot {cosh}^{2} ( A [ S + {σ}_{v}^{2} ] ) \\ where S {=}^{Δ} {lim}_{k \to ∞} E [ {e}_{a}^{2} ( k ) ] . & ( 24 )\end{matrix}$$

In a similar way, D_{S} in (15) can be written as follows:

$${D}_{s} = \frac{E [ {e}_{a} \cdot e \cdot cosh ( {Ae}^{2} ) ]}{E [ {e}_{a}^{2} ]} \qquad ( 25 )$$

Substituting e=eₐ+v into (25) forms

$${D}_{s} = \frac{E [ ( {e}_{a}^{2} + {e}_{a} \cdot v ) cosh ( {Ae}^{2} ) ]}{E [ {e}_{a}^{2} ]} \qquad ( 26 )$$

Based on the assumptions (A1-A6), it can be shown that eₐ is a zero-mean Gaussian variable and is independent of the noise v. Therefore,

$${D}_{s} = \frac{E [ {e}_{a}^{2} cosh ( {Ae}^{2} ) ]}{E [ {e}_{a}^{2} ]} \qquad ( 27 )$$

As before, applying the Cauchy-Schwartz inequality gives

$${D}_{s} \leq \frac{\sqrt{E [ {e}_{a}^{4} ] E [ {cosh}^{2} ( {Ae}^{2} ) ]}}{E [ {e}_{a}^{2} ]} \qquad ( 28 )$$

Applying Jensen's inequality to (28), assuming a priori error to be zero-mean Gaussian, leads to

D_{S}≤\sqrt{3} cos h(A(S+σᵥ²)) (29)

Eventually, using a Taylor series expansion of the hyperbolic cosine function, an approximate closed form expression for the steady-state EMSE in (15) is written as

$$S = \frac{{μ}_{min} Tr [ {R}_{x} ] \cdot {σ}_{v}^{2} [ 1 + \frac{{A}^{2}}{2} {σ}_{v}^{4} ]}{\sqrt{3} - {μ}_{min} Tr [ {R}_{x} ] [ \sqrt{3} + \frac{\sqrt{3}}{2} {A}^{2} {σ}_{v}^{4} + {A}^{2} {σ}_{v}^{6} ]} \qquad ( 30 )$$

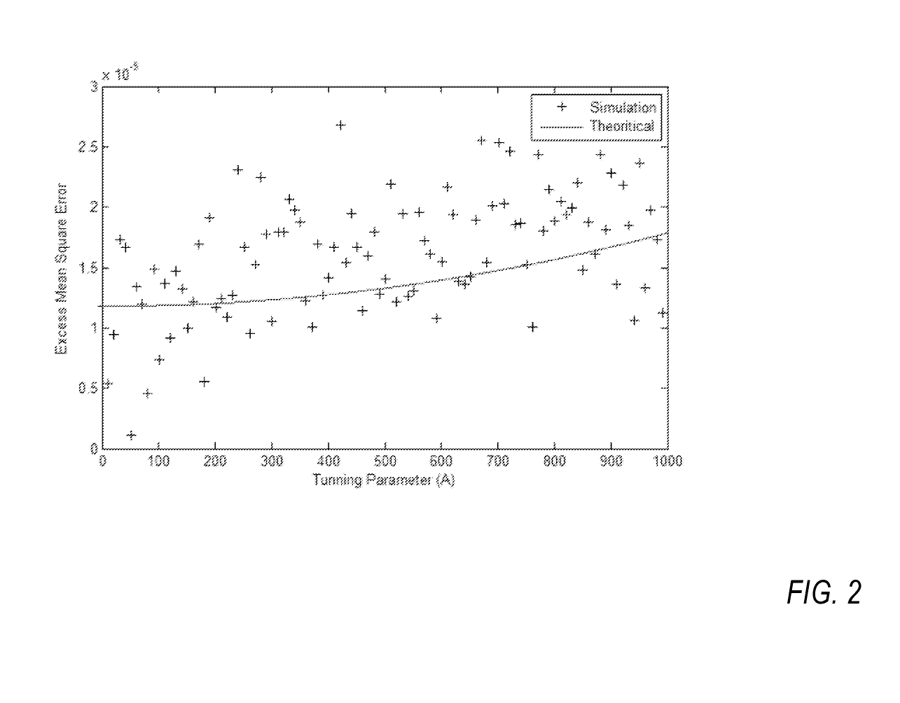

The following remarks are determined from the derived EMSE in (30):
The EMSE depends on the even powers of the noise power.
The EMSE also depends on the tuning parameter A and is usually coupled with the high order even power of the noise variance σᵥ². FIG. 2 reflects the impact of the tuning parameter, A, on the performance of the optimization method of the present disclosure. In FIG. 2, SNR=30 dB, μ=0.01, and Tr[Rₓ]=2. As observed in the graphical representation, EMSE increases with the tuning parameter, creating a supplementary issue at implementation. Additionally, a large A impacts optimization method performance in that it causes a large fluctuation of the EMSE around its average value.
If the tuning parameter A increases such that cosh(Ae²)>μₘₐₓ/μₘᵢₙ for all e², then the optimization method will behave similarly to the LMS optimization method with a fixed μ=μₘₐₓ.
It can be shown from (30) that the EMSE of the optimization method of the present disclosure becomes equal to the EMSE of the LMS by setting A=0. Henceforth, μₘᵢₙ will be referred to as μ_{minLMS} and μₘₐₓ as μ_{maxLMS} to reflect the relationship between the optimization method of the present disclosure and the standard LMS optimization method.

### V. Convergence Analysis

The updated selecting function (8) belongs to the general update equation of the error adaptive filtering optimization method, otherwise referred to as the general class error adaptive filter:

$$\begin{matrix}w ( k + 1 ) = w ( k ) + μ f [ e ( k ) ] x ( k ) \\ where & ( 31 ) \\ f [ e ( k ) ] = \frac{2}{μ} {μ}_{minLMS} \cdot min [ cosh ( {Ae}^{2} ( k ) ) , \frac{{μ}_{maxLMS}}{{μ}_{minLMS}} ] e ( k ) & ( 32 )\end{matrix}$$

Due to the lack of differentiability of the min function in (32), a first derivative cannot be obtained at all points of f(e), and therefore, f[e(k)] can no longer be described as a Taylor series expansion. The approximation, however,

w(k+1)≈w(k)+μ{f{e(k)]x(k)−f′[e(k)]x(k)w^{T}(k)x(k)+1/2f″[e(k)]x(k)[w^{T}(k)x(k)]²} (33)

holds at every point except when e(k)=±δ, where

$$δ = \sqrt{\frac{1}{A} {cosh}^{- 1} ( \frac{{μ}_{maxLMS}}{{μ}_{minLMS}} )}$$

Therefore, the analysis can proceed under the assumption that noise values rarely equal to δ.

### i. Convergence Speed

For a small step size μ, the time-constant of the optimization method of the present disclosure associated with λᵢ(Rₓ) (the i^{th} eigenvalue of the auto-correlation matrix Rₓ) is given by

$${τ}_{i} = \frac{1}{μ E [ {f}^{′} [ e ( k ) ] {λ}_{i} ( {R}_{x} )} \qquad ( 34 )$$

Next, assuming e(k)#±δ, then

$$f ( x ) = \{ \begin{matrix}\frac{2 {μ}_{minLMS}}{μ} x cosh ( {Ax}^{2} ) , & \vert x \vert < δ \\ \frac{2 {μ}_{maxLMS}}{μ} x , & \vert x \vert > δ\end{matrix} \qquad ( 35 )$$

Accordingly,

$$f ( x ) = \{ \begin{matrix}\frac{2 {μ}_{minLMS}}{μ} ( cosh ( {Ax}^{2} ) + 2 {Ax}^{2} sinh ( {Ax}^{2} ) ) , & \vert x \vert < δ \\ \frac{2 {μ}_{maxLMS}}{μ} x , & \vert x \vert > δ\end{matrix} \qquad ( 36 )$$

Eventually, based on (34) and (36), the optimization method of the present disclosure presents the following two cases:

$$\begin{matrix}1 ) if A < \frac{1}{{e}^{2}} {cosh}^{- 1} ( \frac{{μ}_{maxLMS}}{{μ}_{minLMS}} ) then {τ}_{i} = \frac{1}{2 {μ}_{minLMS} E [ cosh ( {Ae}^{2} ) + {Ae}^{2} sinh ( {Ae}^{2} ) ] {λ}_{i} ( {R}_{x} )} & ( 37 ) \\ 2 ) if A > \frac{1}{{e}^{2}} {cosh}^{- 1} ( \frac{{μ}_{maxLMS}}{{μ}_{minLMS}} ) then {τ}_{i} = \frac{1}{2 {μ}_{maxLMS} {λ}_{i} ( {R}_{x} )} & ( 38 )\end{matrix}$$

which match the LMS case for μ=μ_{maxLMS}.

As τ in the first case is smaller than the LMS time-constant, the convergence of the optimization method of the present disclosure, as compared with LMS and certain LMS variants, will be faster. If the tuning parameter A is not properly chosen, then

$$A < \frac{1}{{e}^{2}} {cosh}^{- 1} \\ ( \frac{{μ}_{maxLMS}}{{μ}_{minLMS}} )$$

may not occur and, as a result, the optimization method of the present disclosure will behave similarly to the standard LMS optimization method with μ=μ_{maxLMS} at each point.

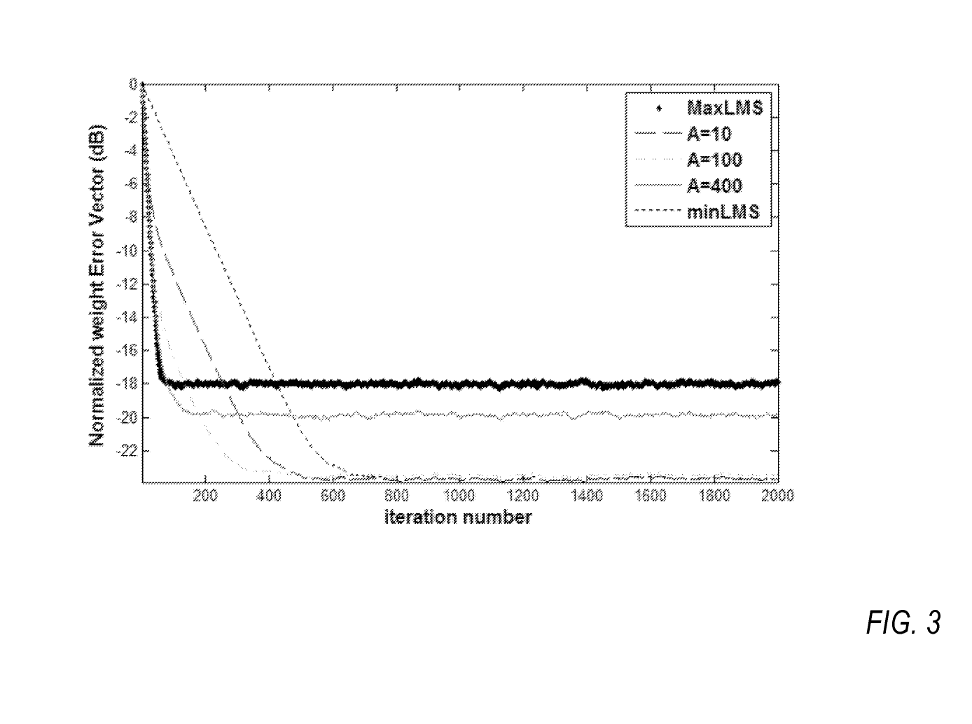

FIG. 3 demonstrates the consequence of varying the tuning parameter A on the convergence speed, wherein the setup is a four taps system identification with a white Gaussian input signal and an additive white Gaussian noise (AWGN) with SNR=30 dB. The convergence speed is noticed to be improved with the tuning parameter, particularly when 10<A<100, while maintaining a consistent steady-state error. When A>100, a trade-off is made between convergence speed and steady-state error, consistent with the results of FIG. 2, and EMSE increases significantly as A moves beyond 100. Generally, for a certain range around A, a similar result can be obtained.

### ii. Step-Size Bounds for Stability

As common in all gradient descent optimization methods, the choice of step-size is critical. To guarantee stability, the step-size must satisfy several bounds.

(8) can be rewritten as

w(k+1)=w(k)+μ(k)e(k)x(k) (39)
where μ(k) is given as

$$μ ( k ) = 2 {μ}_{minLMS} min [ cosh ( {Ae}^{2} ( k ) ) , \frac{{μ}_{maxLMS}}{{μ}_{minLMS}} \qquad ( 40 )$$

It is sufficient to state that the mean value of μ(k), i.e., E[μ(k)], must satisfy the following condition:

$$0 < E [ μ ( k ) ] < \frac{2}{{λ}_{max} ( {R}_{x} )} \qquad ( 41 )$$

where λₘₐₓ is the maximum eigenvalue of the auto-correlation matrix Rₓ.

Based on (40), the following two cases are presented:
1) if cos h

$$( {Ae}^{2} ( k ) ) < ( \frac{{μ}_{maxLMS}}{{μ}_{minLMS}} )$$

then

μ(k)=2 μ_{minLMS}·cos h(Ae²(k)) (42)

Taking expectations of (42), and using the Taylor series expansion, we can approximate E[μ(k)] as

E[μ(k)]≥2 μ_{minLMS}{1+3/2A²F²(k)+3A²F(k)σᵥ²+3/2A²σᵥ⁴} (43)
where F=E[eₐ²] is the instantaneous EMSE and σᵥ² is the variance of the noise. At steady-state, and ignoring the higher order powers of S, a new bound of μ is as follows:

$$0 < {μ}_{minLMS} < \frac{1}{{λ}_{max} ( {R}_{x} ) \{ 1 + 3 {A}^{2} S {σ}_{v}^{2} + \frac{3}{2} {A}^{2} {σ}_{v}^{4} \}} \qquad ( 44 )$$

2) if cos h

$$( {Ae}^{2} ( k ) ) > ( \frac{{μ}_{maxLMS}}{{μ}_{minLMS}} )$$

then

μ(k)=2μ_{maxLMS} (45)
and the new bound will be as follows:

$$0 < {μ}_{minLMS} < {μ}_{maxLMS} < \frac{1}{{λ}_{max} ( {R}_{x} )} \qquad ( 46 )$$

While this bound matches the LMS case, μ_{minLMS} is first chosen as a lower bound.

### VI. Computational Cost

Compared to a standard LMS optimization method, the optimization method of the present disclosure presents additional computational burden per iteration. For example, one comparison, three multiplications, and one hyperbolic cosine term. Rather than calculating the hyperbolic cosine, an appropriate look up table may be used in order to reduce the computational load.

Table I shows the computational complexity of different optimization methods, where M is the order of the filter and N is the total number of samples. We assume that the optimization method of the present disclosure uses a generic μₘₐₓ rather than the fixed maximum step-size (generic μₘₐₓ will be explained in the next section).

| Optimization Method | Multiplication | Addition | Comparison | Look-Up |
|---|---|---|---|---|
| Present Disc. | 3N + 2MN | MN | 1 | cosh |
| Ang | 5N + 2MN | MN | 1 | 0 |
| MVSS | 8N + 8 | 2N + 2 | 2 | 0 |
| MRVSS | 14N + 10 | 4N + 2 | 2 | 0 |
| ECVSS | 3N | 0 | 1 | exp |

It is clear that the computational costs of the optimization method of the present disclosure are still of [symbol] (M). However, when a variable step size is considered, the optimization method of the present disclosure matches ECVSS with respect to computational burden. Additionally, the relatively low number of parameters that must be tuned make it efficiently deployable and attractive in a broad variety of applications.

### VII. Higher Order Hyperbolic Sine Cost Function

LMF optimization methods use even powers of the instantaneous error as a cost function. Generally, though plagued by stability issues, these optimization methods provide a better compromise between convergence speed and steady-state error.

According to an embodiment of the present disclosure, the cost function is a hyperbolic sine cost function which non-linearly adapts the error fourth as the driving argument, defined as

J(k)=sin h(e⁴(k)) (47)

This is a convex and uni-modal function. Its gradient with respect to the filter coefficients yields

Δ_{w}J(k)=−4e³(k)cos h(e⁴(k))x^{T}(k) (48)
where x(k) is the regression vector. To improve the convergence speed, a scale parameter (A>0) can be introduced to scale the squared error, in the argument of the hyperbolic sine. Therefore, the modified cost function will be

$$J ( k ) = \frac{1}{4 A} sinh ( {Ae}^{4} ( k ) ) \qquad ( 49 )$$

while the gradient with the new cost function will be

Δ_{w}J(k)=−e³(k)cos h(Ae⁴(k))x(k) (50)

Hence, the stochastic recursive form of the coefficient estimate is given as

w(k+1)=w(k)+μe³(k)cos h(Ae⁴(k))w(k) (51)

When there is high instantaneous error, the hyperbolic cosine scales up the step-size and, as a result, leads to fast convergence. However, this may also produce optimization method instability. In order to utilize the large gradient property while maintaining a bounded gradient, thus preserving optimization method stability, the following selecting function may be used:

$$w ( k + 1 ) = w ( k ) + {μ}_{min} \cdot min [ cosh ( {Ae}^{4} ( k ) ) , \frac{{μ}_{max}}{{μ}_{min}} ] {e}^{3} ( k ) x ( k ) \qquad ( 52 )$$

where μₘₐₓ and μₘᵢₙ, are the upper and lower bounds of the step-size, μ, respectively.

### i. Steady-State Analysis LMF

In order to evaluate the stead state performance of the above-described fourth order hyperbolic sine cost function-based optimization method, derivation of an approximate EMSE may follow the same approach described for the hyperbolic sine error square cost function, including associated assumptions (e.g., energy conservation relation framework and wide sense stationary channel model assumption).

Following the derivation, the approximate EMSE for the hyperbolic sine of order four argument is as follows:

$$S = \frac{7.5 {μ}_{min} Tr ( {R}_{x} ) \cdot {σ}_{v}^{4} [ 1 + \frac{9}{2} {A}^{2} {σ}_{v}^{8} ]}{9 - 0.5 {μ}_{min} Tr ( {R}_{x} ) [ 45 \sqrt{3} {σ}_{v}^{2} + {ζA}^{2} {σ}_{v}^{10} ]} \qquad ( 53 )$$

where ζ=45/2×9\sqrt{3}+(32/2×15). From the derived EMSE in (53), the following are determined:
The EMSE depends on the even powers of the noise power.
The EMSE is dependent on the tuning parameter A and is further coupled with the high order even power of the noise variance, σᵥ².
If the tuning parameter A increases such that cosh (Ae⁴)>μ_{maxLMF}/μ_{minLMF} for all e⁴, then the optimization method will behave like the LMF optimization method with a fixed μ=μₘₐₓ.
When A=0, the EMSE of the optimization method of the present disclosure, according to (53), is equal to the EMSE of the LMF. Hereafter, μₘᵢₙ will be described as μ_{minLMF}and μₘₐₓ will be described as μ_{maxLMF} to reflect the relationship between the optimization method of the present disclosure and the standard LMF optimization method.

### ii. Convergence Analysis

A convergence analysis, performed via the same methodology as described previously for the hyperbolic sine error squared cost function, can be performed to calculate the following two approximate cases for the cost function of the order four hyperbolic sine:
1) if

$$A < \frac{1}{{e}^{4}} {cosh}^{- 1} ( \frac{{μ}_{maxLMF}}{{μ}_{minLMF}} )$$

then

$${τ}_{i} = \frac{1}{{μ}_{minLMF} E [ 3 {e}^{2} cosh ( {Ae}^{4} ) + 4 {Ae}^{6} sinh ( {Ae}^{4} ) ] {λ}_{i} ( {R}_{x} )} \qquad ( 54 )$$

2) if

$$A > \frac{1}{{e}^{4}} {cosh}^{- 1} ( \frac{{μ}_{maxLMF}}{{μ}_{minLMF}} )$$

then

$${τ}_{i} = \frac{1}{{μ}_{maxLMF} E [ 3 {e}^{2} ] {λ}_{i} ( {R}_{x} )} \qquad ( 55 )$$

which matches the LMF case for μ=μ_{maxLMF}.

Since τ in the first case is smaller than the LMF time-constant, the convergence of the optimization method of the present disclosure is faster than the convergence of the LMF optimization method and certain other LMF variants. If the tuning parameter A is not properly chosen then

$$A < \frac{1}{{e}^{4}} {cosh}^{- 1} ( \frac{{μ}_{maxLMF}}{{μ}_{minLMF}} )$$

may not occur and the optimization method of the present disclosure will operate according to the standard LMF optimization method with a set μ=μ_{maxLMF} for all points.

### iii. Step-Size Bounds for Stability

As common in all gradient descent optimization methods, the choice of step-size is critical to its function. To guarantee stability, the step-size should satisfy a series of bounds.

Equation (52) can be rewritten as:

w(k+1)=w(k)+μ(k)e³(k)x(k) (56)
where μ(k) is given as

$$μ ( k ) = {μ}_{minLMF} min [ cosh ( {Ae}^{4} ( k ) ) , \frac{{μ}_{maxLMF}}{{μ}_{minLMF}} ] \qquad ( 57 )$$

In an instant, the mean value of μ(k), i.e., E[μ(k)], must satisfy the following condition:

$$0 < E [ μ ( k ) ] < \frac{2}{3 {σ}_{v}^{2} {λ}_{max} ( {R}_{x} )} \qquad ( 58 )$$

Based on (57), the following two cases are presented:

1) if cos h

$$( {Ae}^{4} ( k ) ) < ( \frac{{μ}_{maxLMF}}{{μ}_{minLMF}} )$$

then

μ(k)=μ_{minLMF}·cos h(Ae⁴(k)) (59)

Including (59), and using the Taylor series expansion, E[μ(k)] can be approximated as

$$E [ μ ( k ) ] \geq {μ}_{minLMF} \{ 1 + \frac{9 ( 70 )}{2} {A}^{2} {F}^{2} ( k ) {σ}_{v}^{4} + \frac{15 ( 28 )}{2} {A}^{2} F ( k ) {σ}_{v}^{6} + \frac{105}{2} {A}^{2} {σ}_{v}^{8} \} \qquad ( 60 )$$

where F=E[e²ₐ]. At steady-state, one can drop the high order powers of S, implying a new bound of μ, as follows:

$$0 < {μ}_{minLMF} < \frac{2}{3 {σ}_{v}^{2} {λ}_{max} ( {R}_{x} ) \{ 1 + 315 {A}^{2} S {σ}_{v}^{6} + 52.5 {A}^{2} {σ}_{v}^{8} \}} \qquad ( 61 )$$

2) if cos h

$$( {Ae}^{4} ( k ) ) > ( \frac{{μ}_{maxLMF}}{{μ}_{minLMF}} )$$

then

μ(k)=μ_{maxLMF} (62)
and the new bound is:

$$0 < {μ}_{minLMF} < {μ}_{maxLMF} < \frac{2}{3 {σ}_{v}^{2} {λ}_{max} ( {R}_{x} )} \qquad ( 63 )$$

While this bound matches the LMF case, μ_{minLMF} is first chosen as a lower bound.

### VIII. Mixed-Norm Hyperbolic Sine Cost Function

According to an embodiment of the present disclosure, the cost function is a hyperbolic sine cost function which non-linearly adapts the second and fourth error moments as the driving argument. The pursuant optimization method embodies the concept of normalizing error and combining it with a generic upper bound value for μ, wherein μ is a generic value rather than a fixed number. One can evaluate μₘₐₓ at each iteration as follows:

$${μ}_{max} = \frac{1}{Tr [ Rx ] + ϵ} \cdot \frac{1}{1 + {e}_{.}^{2} ( k )} \qquad ( 64 )$$

where ϵ«1 is used to avoid the case of a zero value denominator. By using this generic value, the stability of the optimization method is ensured while improving the convergence speed. Moreover, by introducing a normalized error, the optimization method of the present disclosure is imbued with the stability of LMS and the decreased steady-state error achieved by LMF.

Normalizing the error will work to balance the mixture between second order and fourth order moments, compared with traditional approaches where the balance factor is always fixed. A steady-state analysis can be conducted with an approach similar to that which was deployed for the second order hyperbolic sine cost function and the fourth order hyperbolic sine cost function, independently. Accordingly, the convergence analysis renders the following two cases:
1) if cos h

$$( {Ae}^{4} ( k ) ) < ( \frac{{μ}_{maxLMF}}{{μ}_{minLMF}} )$$

then the equation will be

w(k+1)=w(k)+μe³(k)cos h(Ae⁴(k))x(k) (65)
which matches the LMF equation.
2) if cosh

$$( {Ae}^{4} ( k ) ) > ( \frac{{μ}_{maxLMF}}{{μ}_{minLMF}} )$$

then me equation will be

$$w ( k + 1 ) = w ( k ) + \frac{cosh ( {Ae}^{4} ( k ) ) x ( k )}{Tr [ {R}_{x} ] + ϵ} \cdot \frac{{e}^{3} ( k )}{1 + {e}^{2} \cdot ( k )} \qquad ( 66 )$$

In the second case, the normalized error is as follows:
a) if error is small then

$$\frac{{e}^{3} ( k )}{1 + {e}^{2} \cdot ( k )} \approx {e}^{3} ( k ) \qquad ( 67 )$$

which mimics the LMF behavior where the fourth moment is dominant.
b) if error is large then

$$\frac{{e}^{3} ( k )}{1 + {e}^{2} \cdot ( k )} \approx e ( k ) \qquad ( 68 )$$

which mimic the LMS behavior where the second moment is dominant.

The above approximates a natural mix between the second and fourth moments of error driven by the instantaneous error. Specifically, from (67) and (68), instead of controlling the amount of mix via a single parameter, error becomes the driver of the mix norm, where the cost function is a fourth order moment and the error function is normalized.

### IX. Simulation Results

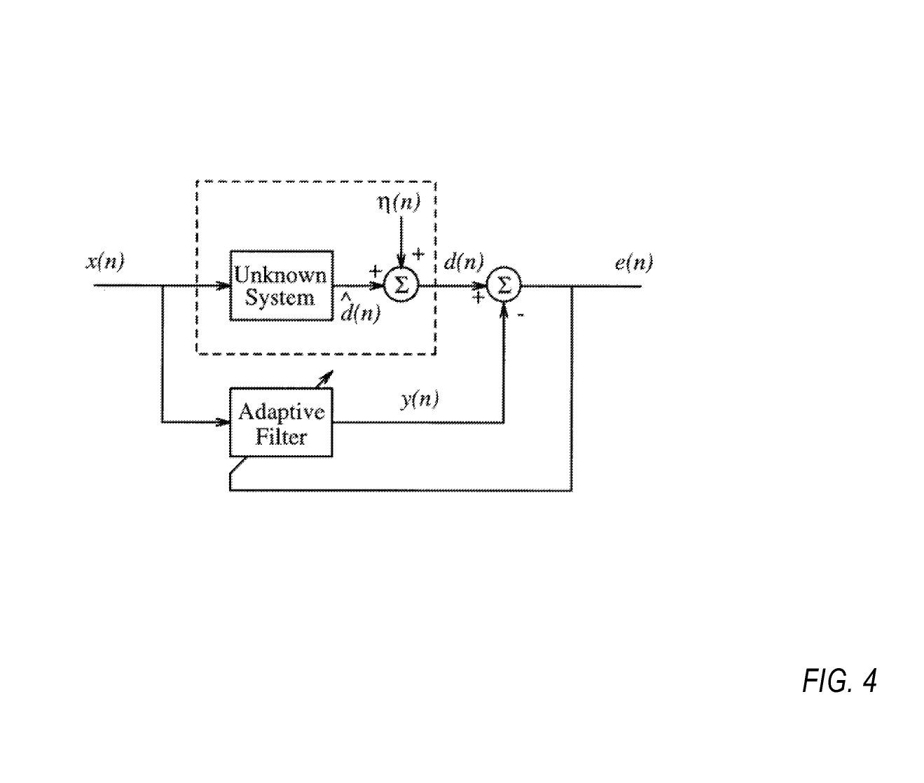

Simulation results were carried out for system identification scenarios. FIG. 4 presents a generalized approach to system identification, wherein a “black box” encloses an unknown system, the unknown system comprising quantities that are not visible from the outside. With reference to FIG. 4, the “black box” contains the unknown system, representing a general input-output relationship, and a corrupting signal η(n) that corrupts the observations of the signal at the output of the unknown system, \hat{d}(n). Assuming \hat{d}(n) represents the output of the unknown system with x(n) as its input, the desired response signal, d(n) can be modeled as d(n)=\hat{d}(n)+(n). In this system identification scenario, the task of the adaptive filter is to accurately represent the signal \hat{d}(n) at the output. In doing so, the adaptive filter employs a cost function that is representative of the error signal. The objective of the adaptive filter, therefore, is to minimize the cost function, thus making progress toward accomplishing the task described above. When y(n)=\hat{d}(n), the adaptive filter has accurately modeled or identified the portion of the unknown system that is driven by x(n). In an application, an ideal adaptation procedure modifies W(n), the set of filter coefficients, such that y(n) closely approximates \hat{d}(n) over time.

In the present disclosure, and further in context of the generalized system identification model of FIG. 4, the adaptive filter coefficients are all initialized at zero. The output of the unknown system is corrupted with a zero-mean white Gaussian noise sequence, v(k). The variance, σᵥ², of the noise sequence is selected in accordance with the desired SNR. All experiments are averaged over 200 independent realizations. The quantitative performance measure is the normalized weight error squared vector in dB, which is mathematically calculated as

$$ℳ = 10 {log}_{10} ( \frac{E [ {‖ {w}^{o} - w ( k ) ‖}^{2} ]}{{‖ {w}^{o} ‖}^{2}} )$$

where w^{o}=[w₀^{o}, w₁^{o}, . . . w_{M}_{ₒ}₋₁]^{T} is the true values of the unknown system/channel taps and weights and W(k)=[w₀(k), w₁(k), . . . , w_{M-1}(k)]^{T} is the values of the digital filter coefficients at time instant k, with M as the filter order assuming both are the same order, and [.]^{T} the transpose of the matrix/vector. In other words, the above reflects the impulse response of the linear time invariant (LTI) unknown system/channel.

In order to fairly evaluate the optimization method of the present disclosure against others in the literature, different experiments will be conducted based on the simulation environment used in the referenced optimization methods.

### Example 1—LMS Family (see Ang and Farhang-Boroujeny, “A new class of Gradient Adaptive Step-Size LMS Algorithms”, IEEE Transactions on Signal Processing, Vol. 49, No. 1, 2001; Referred to Herein as the “Ang Method” and Incorporated by Reference in its Entirety)

According to an embodiment of the present disclosure, the adaptive filter and the unknown system are both of order 16, the input signal is zero-mean white Gaussian noise (of unit variance), the desired signal is corrupted by AWGN with zero-mean, and the SNR is 20 dB. The multiplicative optimization method, as recommended by Ang and Farhang-Boroujeny, was used in place of the linear counterpart optimization method. The Ang method parameter values are as follows: α=0.95 and ρ=2×10 ⁻⁴. Further, the Ang method was initialized with μₘₐₓ to provide a high initial convergence speed. The optimization method of the present disclosure used a tuning parameter A=10 and μ_{minLMS} was chosen such that a similar steady-state misadjustment level to Ang was achieved. Similar to Ang,

$${μ}_{m axLMS} = \frac{1}{Tr [ {R}_{x} ]} .$$

In testing the optimization methods tractability, a sudden change was introduced at iteration 4000 by multiplying all filter coefficients of the unknown system by −1.

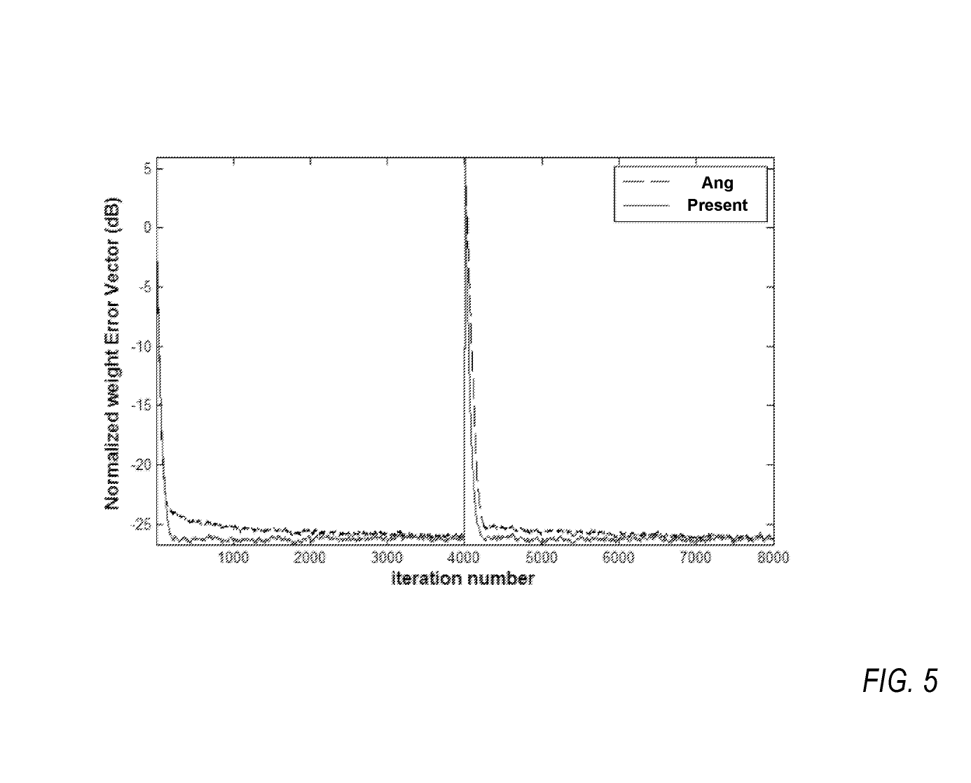

FIG. 5 is a graphical representation of the adaptive curves of the optimization method of the present disclosure and the Ang method. As illustrated in FIG. 5, the optimization method of the present disclosure converges faster than the Ang method. Moreover, the optimization method of the present disclosure demonstrates improved performance while consuming minimal computational energy and requiring fewer tuning parameters.

### Example 2—LMS-family (see Aboulnasr and Mayyas, “A robust variable step-size LMS-type algorithm: analysis and simulations”, IEEE Transactions on Signal Processing, Vol. 45, No. 3, 1997; referred to herein as the “MVSS method” and incorporated by reference in its entirety)

According to an embodiment of the present disclosure, the adaptive filter and the unknown system are both of order 4, the input signal is zero-mean white Gaussian noise, the desired signal is corrupted by AWGN noise with zero-mean, and the SNR is 30 dB. The parameters of the MVSS method are assigned as follows: α=0.97, β=0.99, γ=1, μₘₐₓ=0.1, μₘᵢₙ=5×10 ⁻⁴. The MVSS method was initialized with μₘₐₓ to provide a high initial convergence speed. For the optimization method of the present disclosure, the tuning parameter was set to A=120,

$${μ}_{m axLMS} = \frac{1}{Tr [ {R}_{x} ]} . ,$$

and μ_{minLMS} was chosen to give a steady-state misadjustment level similar to that obtained by the MVSS method. At iteration 3000, an abrupt change was introduced, similar to Example 1.

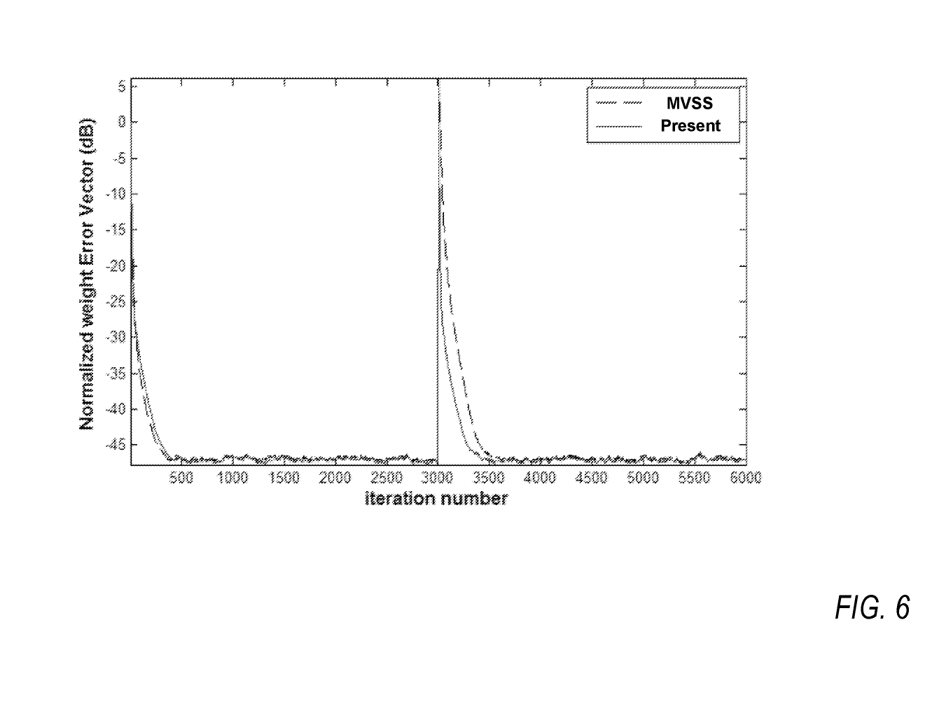

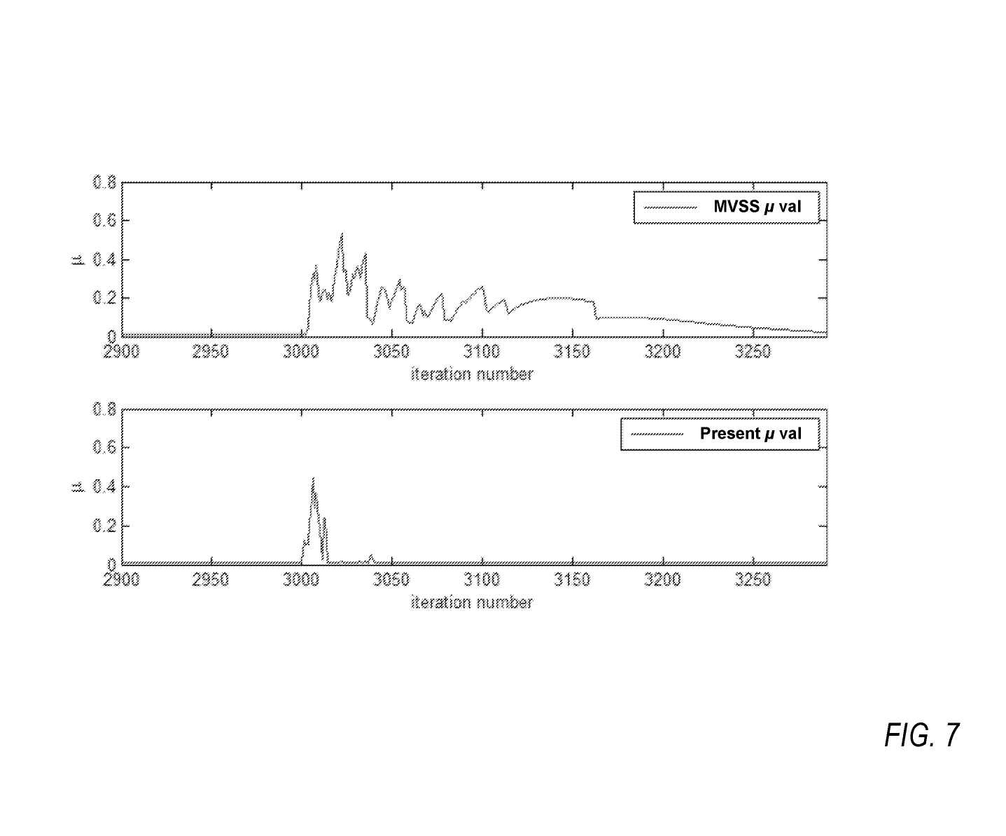

FIG. 6 is a graphical representation of the adaptive curves of the optimization method of the present disclosure and the MVSS method. The optimization method of the present disclosure initially converges at the same speed as the MVSS method; however, following perturbation at iteration 3000, the MVSS is delayed in adapting. The ability of the optimization method of the present disclosure to outperform the MVSS method required an investigation into the variation of the adaptive parameter, μ, of both optimization methods, as illustrated in FIG. 7. As is seen in FIG. 7, the optimization method of the present disclosure has the ability to stabilize the unit step faster and to reach a lower steady-state misadjustment more quickly than the MVSS method.

### Example 3—LMS-Family (see Zhao, et al., “A Fast Variable Step-Size LMS Algorithm with System Identification”, 2^{nd} IEEE Conference on Industrial Electronics and Applications, 2007; Referred to Herein as the “MRVSS Method” and Incorporated by Reference in its Entirety)

According to an embodiment of the present disclosure, the adaptive filter and the unknown system are both of order 4, the input signal is zero-mean white Gaussian noise, the desired signal is corrupted by AWGN noise with zero-mean, and the SNR is 30 dB. The parameters of the MRVSS method are assigned as follows: α=0.97, α=0.995, b=1×10⁻⁵, μₘₐₓ=0.1. The MRVSS method was initialized with μₘₐₓ to provide a high initial convergence speed. For the optimization method of the present disclosure, the tuning parameter was set to A=100 and μ_{minLMS} was chosen to give an acceptable steady-state misadjustment level, while μ_{maxLMS} was used in the MRVSS method. At iterations 3000, 5000, 7000, and 9000, all coefficients of the unknown system were multiplied by −1 in order to test the optimization methods ability to track sudden changes, similar to Example 1.

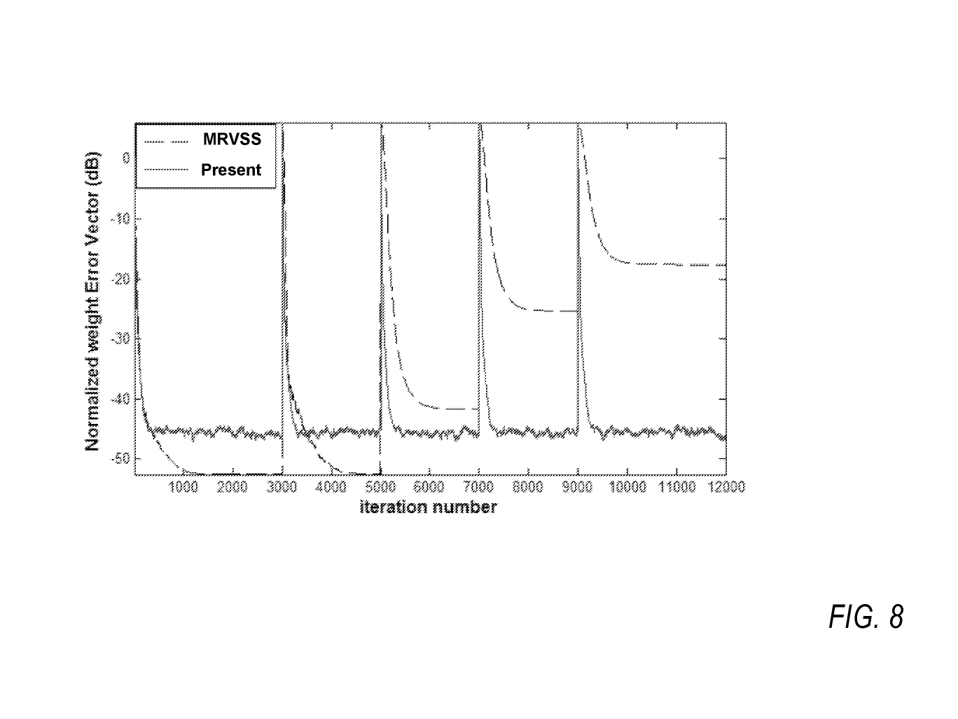

FIG. 8 is a graphical representation of the adaptive curves of the optimization method of the present disclosure and the MRVSS method, with SNR=30 dB. The optimization method of the present disclosure matches the MRVSS method with respected to convergence speed while it can be observed that the MRVSS method achieves a lower steady-state misadjustment level. While a lower steady-state misadjustment level is achieved, the MRVSS method exhibits poor tracking ability. For instance, following successive perturbations of the system, the tracking ability of the MRVSS method worsens, while the optimization method of the present disclosure is able to adapt rapidly and return to a low steady-state misadjustment level. This is due, in part, to the MRVSS method's dependency on cumulative error, which is heavily impacted by sudden changes that lead to increases in instantaneous error and, ultimately, increases in cumulative error.

### Example 4—LMS Family (see Rusu and Cowan, “The exponentiated convex Variable Step-Size (ECVSS) Algorithm”, Signal Processing, Vol. 90, No. 9, 2010; Referred to Herein as the “ECVSS Method” and Incorporated by Reference in its Entirety)

According to an embodiment of the present disclosure, the adaptive filter and the unknown system are both of order 32 with an impulse response of H(z)=Σₙ₌₀σⁿZ⁻ⁿ, where σ=0.80025. All coefficients were normalized to |H(z)|. The input signal is a zero-mean random bipolar sequence from {1, +1}, the desired signal is corrupted by AWGN with zero-mean, and the SNR is 30 dB. In order to establish a steady-state adjustment level similar to the optimization method of the present disclosure, while maintaining rapid convergence, the A parameter of the ECVSS method was set to 35. Per Rusu and Cowan, μₘₐₓ=0.008565 and μₘᵢₙ=0.0008565.

The optimization method of the present disclosure was given a tuning parameter A=100, with the same μ_{minLMS} as the ECVSS method, such that a similar steady-state misadjustment level would be achieved.

$${μ}_{m axLMS} = \frac{1}{Tr [ {R}_{x} ]} .$$

Following 4000 iterations, all the coefficients of the unknown system were multiplied by −1 in order to test each optimization method's ability to track sudden changes, similar to Example 1.

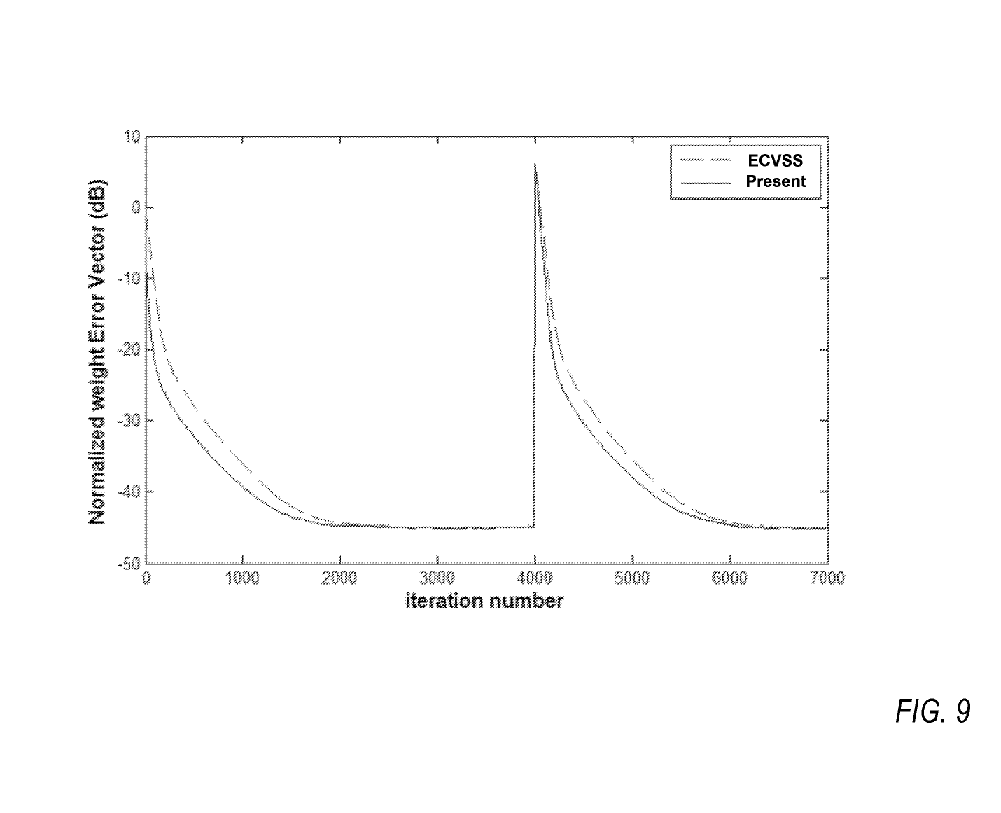

FIG. 9 is a graphical representation of the adaptive curves of the optimization method of the present disclosure and the ECVSS method, with SNR=30 dB. It can be observed that the optimization method of the present disclosure converges more quickly and tracks faster than the ECVSS method initially, including following the perturbation at 4000 iterations.

### Example 5—LMF Family (Standard LMF)

According to an embodiment of the present disclosure, the adaptive filter and the unknown system are both of order 5. The input signal is a uniform zero-mean random bipolar sequence from {1, +1}, the desired signal is corrupted by sub-Gaussian noise, and the SNR is 10 dB. The step size, μ, was set to 0.001. The optimization method of the present disclosure was assigned a scaling parameter A=100 and μₘₐₓ=0.01. In order to achieve the same steady-state misadjustment across the optimization methods, μₙₜₕ, was set to 0.001, matching the LMF μ.

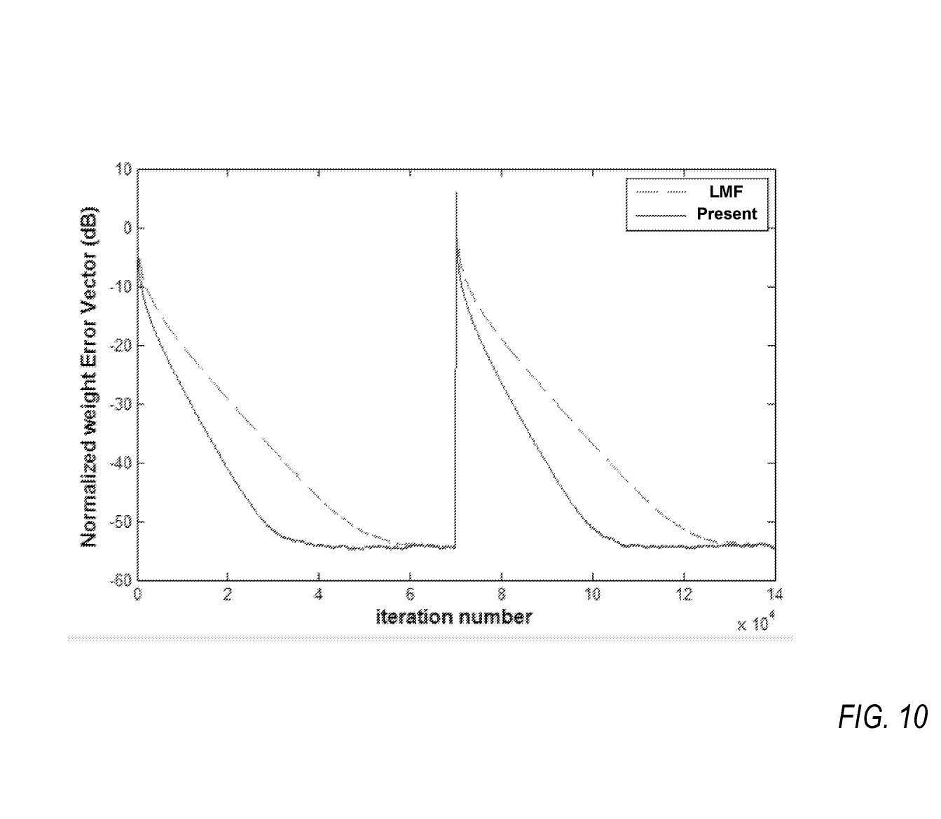

FIG. 10 is a graphical representation of the adaptive curves for the optimization method of the present disclosure and the LMF optimization method. As indicated by the position of the lines during the first 140,000 iterations of the experiment, the optimization method of the present disclosure displays faster convergence to the same steady-state misadjustment level with improved tracking as compared with the LMF optimization method.

### Example 6—LMF-Family (see bin Mansoor, et al., “Stochastic Gradient Algorithm Based on an Improved Higher Order Exponentiated Error Cost Function”, Asilomar Conference on Signals, Systems and Computers, 2014; Referred to Herein as the “EELMF Method” and Incorporated by Reference in its Entirety)

According to an embodiment of the present disclosure, the adaptive filter and the unknown system are both of order 5. The input signal is bipolar {1, −1}, the desired signal is corrupted by sub-Gaussian noise with zero-mean, and the SNR is 10 dB. In order to maintain stability, the maximum scaling parameter used in the EELMF method is k=0.14. The step size, μ, was set to 0.001. In the optimization method of the present disclosure, the tuning parameter was set to A=100 and μ_{minLMF} was chosen to be similar to the EELMF method to ensure a similar steady-state misadjustment level. μ_{maxLMF} was set to 0.01.

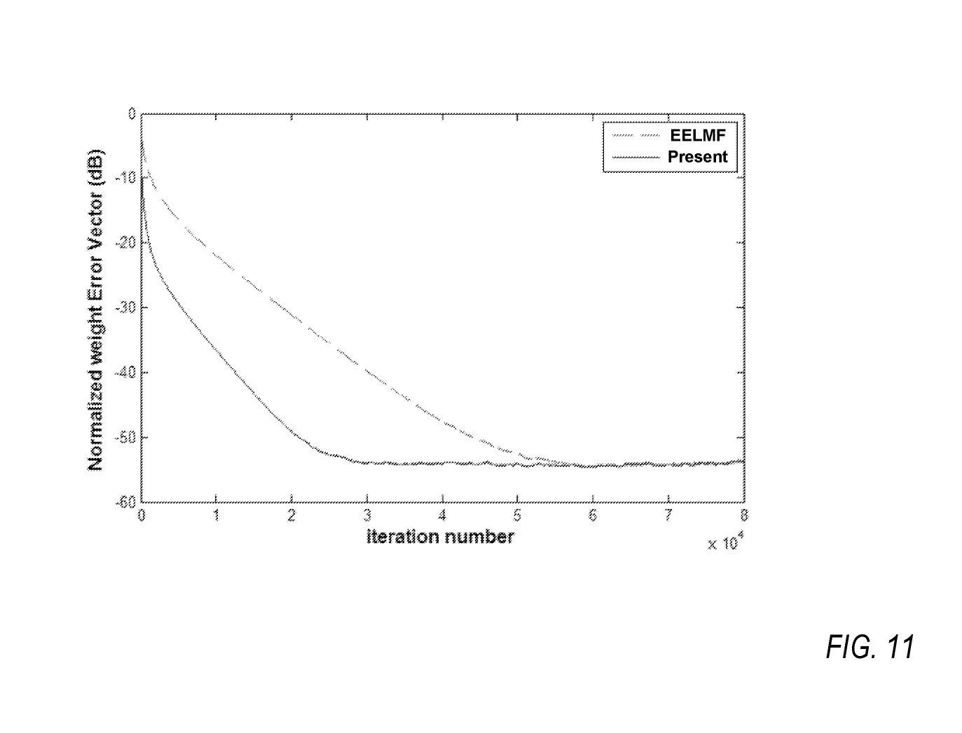

FIG. 11 is a graphical representation of the adaptive curves of the optimization method of the present disclosure and the EELMF method. As can be seen in FIG. 11, over the first 60,000 iterations, it can be observed that the optimization method of the present disclosure more quickly converges to the steady-state misadjustment level.

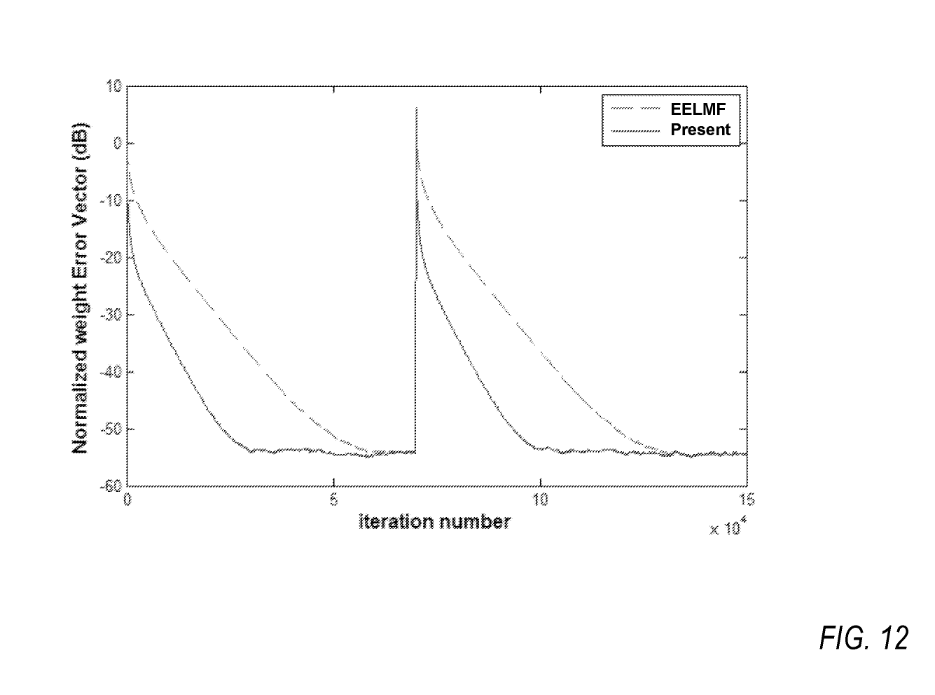

As shown in FIG. 12, LMF-family optimization methods suffer from poor tracking ability. At initialization, all values of the filter coefficients are zero, and so the instantaneous error has a certain value. Following a sudden change, for instance, multiplying the filter coefficients by −1 while the filter is operating at steady-state, the instantaneous error value will be similar to the filter coefficients at initialization, which may lead the optimization method to diverge.

To test this tracking ability, the maximum scaling parameter of the EELMF method was set to k=0.009 and an experiment following the same approach to FIG. 11 was performed. The optimization method of the present disclosure required no modification. At iteration 7,000, all filter coefficients were multiplied by −1, similar to Example 1.

FIG. 12 is a graphical representation of the adaptive curves of the optimization method of the present disclosure and the EELMF method following perturbation. As is visible following 7,000 iterations, the optimization method of the present disclosure more quickly adapts and converges to the steady-state misadjustment level than the EELMF method.

### Example 7—LMF-Family (see Zerguine, et al., “A Hybrid LMS-LMF Scheme for Echo Cancellation”, IEEE International Conference on Acoustics, Speech, and Signal Processing, 1997; Referred to Herein as the “LMS-LMF Type II Method” and Incorporated by Reference in its entirety)

According to an embodiment, and similar to the optimization method of the present disclosure, the LMS-LMF Type II method employs two different μ. For the evaluation, the adaptive filter and the unknown system are both of order 16. The input signal is white-Gaussian with zero-mean, the desired signal is corrupted by sub-Gaussian noise with zero-mean, and the SNR is 10 dB. For the LMS-LMF Type II method, μ₁ is set to 0.03 and μ₂ is set to 0.001. For the optimization method of the present disclosure, the tuning parameter A is set to 100, μ_{maxLMF}=0.002 and μ_{minLMF} =0.001. At iteration 7,000, all filter coefficients were multiplied by −1.

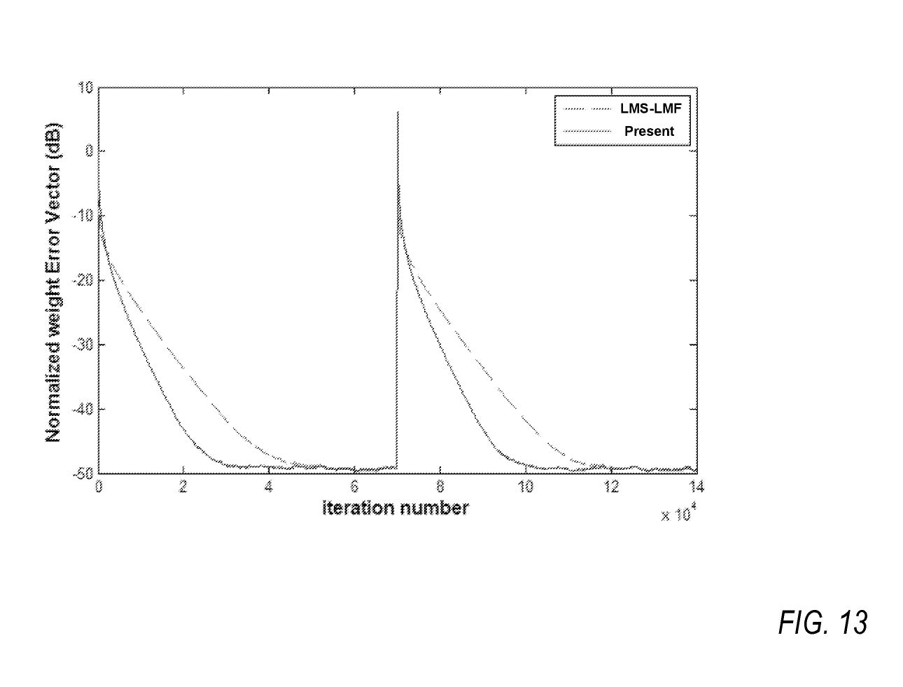

FIG. 13 is a graphical representation of the adaptive curves of the optimization method of the present disclosure and the LMS-LMF Type II method. As visible following perturbation at 7,000 iterations, the optimization method of the present disclosure converges more quickly and with faster tracking back to the steady-state misadjustment level.

### Example 8—Mixed-Norm Family (see LMS-LMF Type II; see Sayin, et al., “A Novel Family of Adaptive Filtering Algorithms Based on the Logarithmic Cost”, IEEE Transactions on Signal Processing, Vol. 62, No. 17, 2014; Referred to Herein as the “Logarithmic Method” and Incorporated by Reference in its Entirety)

Next, an evaluation of the optimization method of the present disclosure compared with a logarithmic cost function method (“Logarithmic method”) and the LMS-LMF Type II method is completed.

According to an embodiment of the present disclosure, for all systems, the adaptive filter and the unknown system are of order 5. The input signal is a uniform zero-mean random bipolar sequence from {−1, +1}, the desired signal is corrupted by sub-Gaussian noise, and the SNR is 10 dB. For the reference optimization methods, the step-size, μ, was set to 0.001. For the optimization method of the present disclosure, the scaling parameter A was set to 100 and μ was tuned such that all three optimization methods would have the same steady-state misadjustment level in order to have a fair comparison. For the LMS-LMF Type II method, μ₁ was selected to maximize convergence speed while μ₂ was selected in order to reach the same steady-state misadjustment level as the other optimization methods.

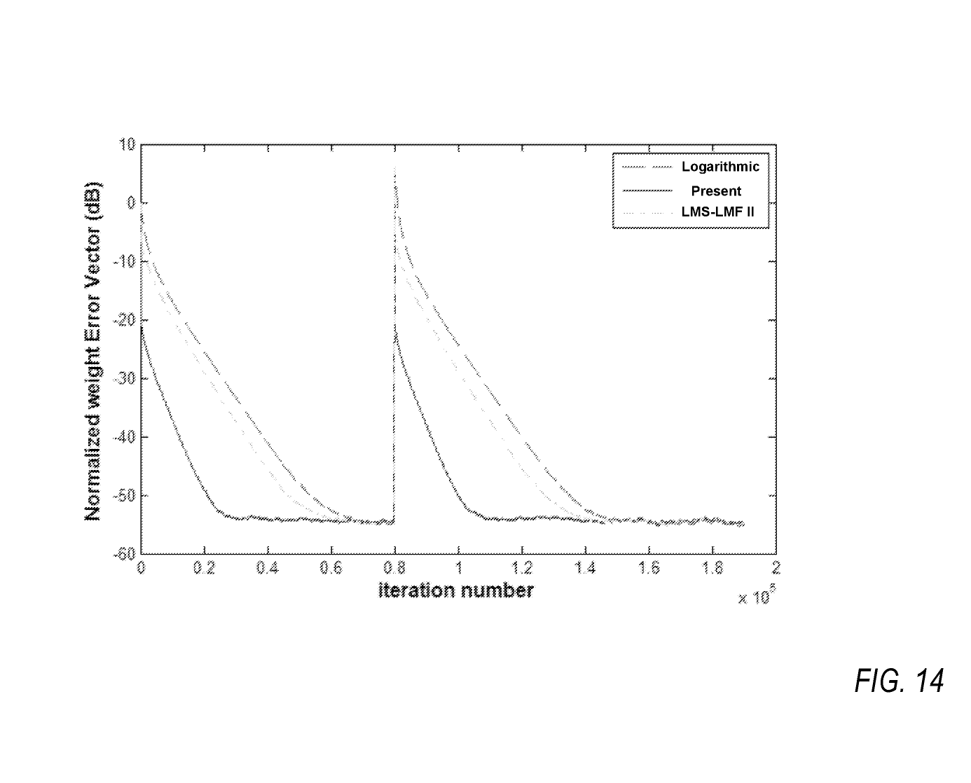

FIG. 14 is a graphical representation of the adaptive curves of the optimization method of the present disclosure, the Logarithmic method, and the LMS-LMF Type II method. Similar to FIG. 13, it is demonstrated that the optimization method of the present disclosure converges more quickly to the steady-state misadjustment level and with faster tracking ability than the optimization methods under comparison.

### Example 9 -Mixed-Norm Family

Next, according to an embodiment of the present disclosure, the robustness of the optimization method of the present disclosure under three types of noise distributions was evaluated. All noise distributions (Gaussian, Uniform, and Laplacian) have the same noise power. A similar evaluation approach to Example 5 was employed.

According to an embodiment of the present disclosure, the adaptive filter is of order 5. The input signal is a uniform zero-mean random bipolar sequence from {−1, +1}, the desired signal is corrupted with the noise distributions described above, and the SNR is 10 dB.

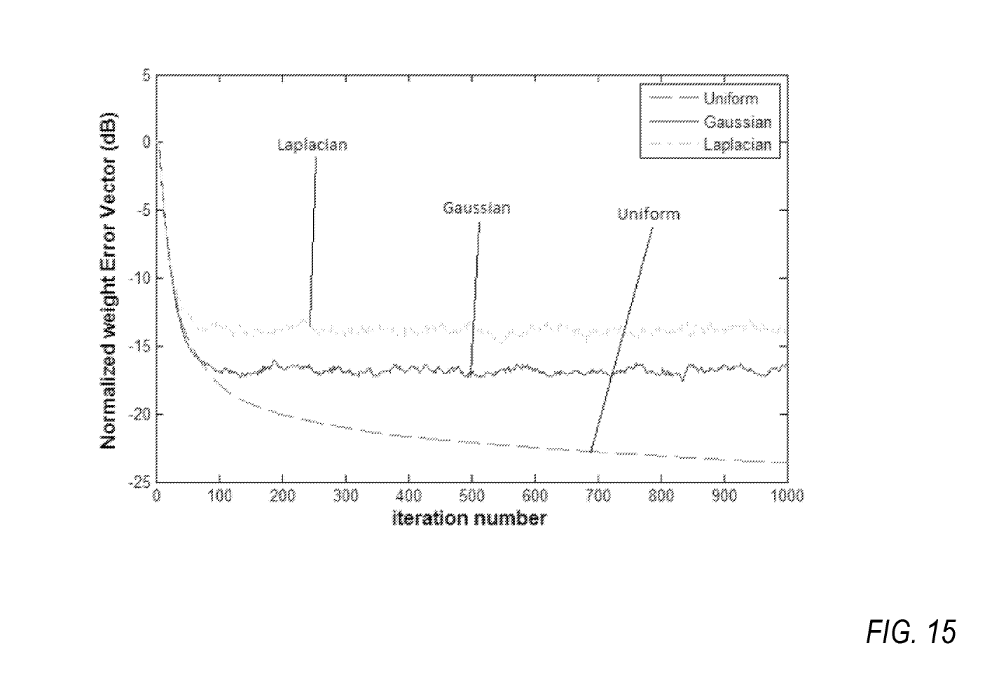

FIG. 15 is a graphical representation of the adaptive curves of the optimization method of the present disclosure under different noise conditions. As the optimization method of the present disclosure relies upon higher order moments in the steady-state region, the best performance was observed under a uniform noise distribution environment.

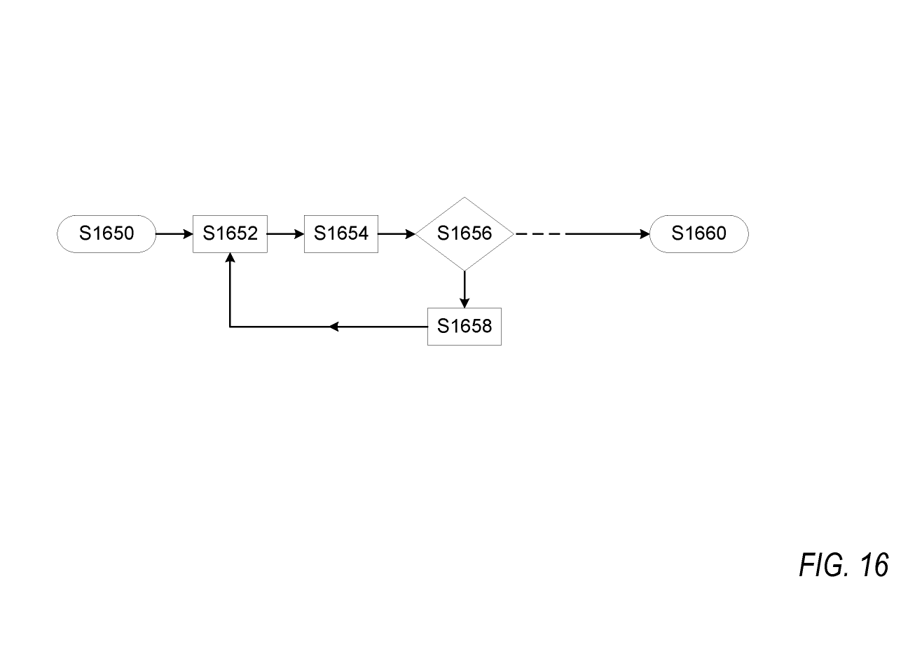

According to an embodiment of the present disclosure, FIG. 16 describes a method employing the adaptive filtering optimization methods described above. At S1650, processing circuitry receives an input signal, or input value. In an exemplary embodiment of the present disclosure, and in a non-limiting manner, the input signal is an electrical signal. Based on an initial set of one or more filter coefficients S1652, the processing circuitry generates an initial output signal, or initial output value. An error signal, or error value, is determined as the difference between the initial output value and a desired response signal S1654, or desired response value. From the error value, a solution to a cost function is calculated S1656. In order to minimize the solution to the cost function calculated in S1656, the set of one or more filter coefficients may be adjusted S1658, or updated, to establish a subsequent set of one or more filter coefficients. Following adjustment, the processing circuitry again generates a subsequent output value S1652 based upon the subsequent set of one or more filter coefficients, determines an error value S1654, and calculates a solution to the cost function S1656. In practice, the processing circuitry modifies the set of one or more filter coefficients according to an adaptive filtering optimization method in context of the associated cost function. According to an embodiment, the adaptive filtering optimization method is an optimization method of the present disclosure. The above-described steps can be performed iteratively S1660 in order to arrive at and maintain a steady-state misadjustment level.

In an example, the optimization method of the present disclosure can be applied to estimating the impulse response of a small audio loudspeaker for determining the combined impulse response of a loudspeaker/room/microphone sound propagation path, wherein the loudspeaker and microphone are to be used in active noise control tasks. In other instances, and in a non-limiting manner, the optimization method of the present disclosure can be applied to adaptive control, electrical power, adaptive noise cancelling, echo cancellation for long-distance transmission, and acoustic echo cancellation.

In another embodiment, the optimization methods of the present disclosure may be applied to channel identification. For example, it is known that communications are often transmitted from one point to another via a medium such as an electrical wire, optical fiber, or wireless radio link. Non-idealities of the transmission medium, or channel, distort the fidelity of the transmitted signals, making deciphering the received information difficult. In cases where the effects of the distortion can be modeled as a linear filter, the resulting “smearing” of the transmitted symbols is known as inter-symbol interference (ISI). In these cases, an adaptive filter can be used to model the effects of the channel ISI for the purpose of deciphering the received information in an optimal manner. In this scenario, the transmitter sends to the receiver a sample sequence x(n) that is known to both the transmitter and receiver. The receiver then attempts to model the received signal d(n) using an adaptive filter whose input is the known transmitted sequence x(n). After a suitable period of adaptation, or optimization, via the selected optimization method of the present disclosure, the parameters of the adaptive filter in W(n) may be fixed and then used to decode future signals transmitted across the channel.

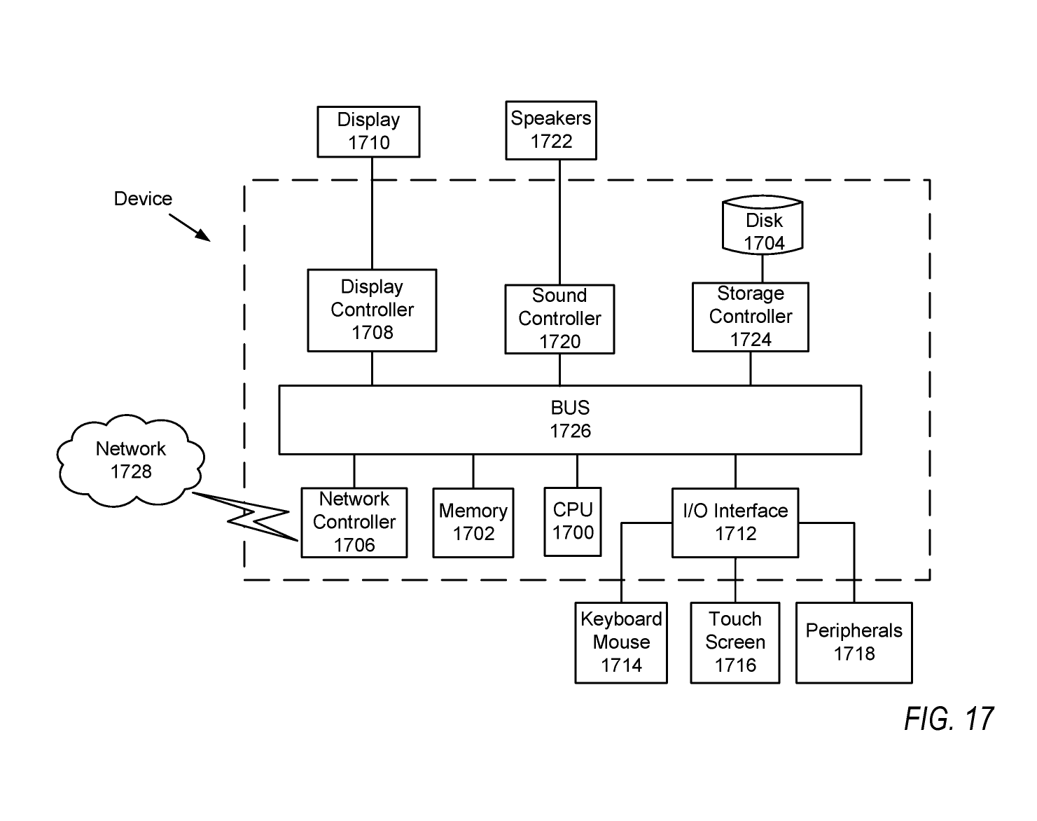

Next, with reference to FIG. 17, a hardware description of a device implementing one of the one or more above-described adaptive filtering optimization methods, according to exemplary embodiments, is described. In FIG. 17, the device includes a CPU 1700 which performs the processes described above/below. The process data and instructions may be stored in memory 1702. These processes and instructions may also be stored on a storage medium disk 1704 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the device communicates, such as a server or computer.

Further, the claimed advancements may be provided as a utility application, background daemon, or component of an operating system, or combination thereof, executing in conjunction with CPU 1700 and an operating system such as Microsoft Windows 7, UNIX, Solaris, LINUX, Apple MAC-OS and other systems known to those skilled in the art.

The hardware elements in order to achieve the device may be realized by various circuitry elements, known to those skilled in the art. For example, CPU 1700 may be a Xenon or Core processor from Intel of America or an Opteron processor from AMD of

America, or may be other processor types that would be recognized by one of ordinary skill in the art. Alternatively, the CPU 1700 may be implemented on an FPGA, ASIC, PLD or using discrete logic circuits, as one of ordinary skill in the art would recognize. Further, CPU 1700 may be implemented as multiple processors cooperatively working in parallel to perform the instructions of the inventive processes described above.

The device in FIG. 17 also includes a network controller 1706, such as an Intel Ethernet PRO network interface card from Intel Corporation of America, for interfacing with network 1728. As can be appreciated, the network 1728 can be a public network, such as the Internet, or a private network such as an LAN or WAN network, or any combination thereof and can also include PSTN or ISDN sub-networks. The network 1728 can also be wired, such as an Ethernet network, or can be wireless such as a cellular network including EDGE, 3G and 4G wireless cellular systems. The wireless network can also be WiFi, Bluetooth, or any other wireless form of communication that is known.

The device further includes a display controller 1708, such as a NVIDIA GeForce GTX or Quadro graphics adaptor from NVIDIA Corporation of America for interfacing with display 1710, such as a Hewlett Packard HPL2445w LCD monitor. A general purpose I/O interface 1712 interfaces with a keyboard and/or mouse 1714 as well as a touch screen panel 1716 on or separate from display 1710. General purpose I/O interface also connects to a variety of peripherals 1718 including printers and scanners, such as an OfficeJet or DeskJet from Hewlett Packard.

A sound controller 1720 is also provided in the device, such as Sound Blaster X-Fi Titanium from Creative, to interface with speakers/microphone 1722 thereby providing sounds and/or music.

The general purpose storage controller 1724 connects the storage medium disk 1704 with communication bus 1726, which may be an ISA, EISA, VESA, PCI, or similar, for interconnecting all of the components of the device. A description of the general features and functionality of the display 1710, keyboard and/or mouse 1714, as well as the display controller 1708, storage controller 1724, network controller 1706, sound controller 1720, and general purpose I/O interface 1712 is omitted herein for brevity as these features are known.

Obviously, numerous modifications and variations are possible in light of the above teachings. It is therefore to be understood that within the scope of the appended claims, the invention may be practiced otherwise than as specifically described herein.

Thus, the foregoing discussion discloses and describes merely exemplary embodiments of the present invention. As will be understood by those skilled in the art, the present invention may be embodied in other specific forms without departing from the spirit or essential characteristics thereof. Accordingly, the disclosure of the present invention is intended to be illustrative, but not limiting of the scope of the invention, as well as other claims. The disclosure, including any readily discernible variants of the teachings herein, defines, in part, the scope of the foregoing claim terminology such that no inventive subject matter is dedicated to the public.

1. A method for adaptive filtering, the method comprising:
receiving, via processing circuitry, an input signal;
generating, via the processing circuitry, an initial output signal based upon an initial set of one or more coefficients;
determining, via the processing circuitry, an error signal based upon the difference between the initial output signal and a desired response signal;
calculating, via the processing circuitry, a solution to a function based upon the error signal; and
generating, via the processing circuitry, a subsequent output signal based upon a subsequent set of one or more coefficients,
wherein the subsequent set of one or more coefficients is determined by adjusting the initial set of one or more coefficients based upon the calculation of the solution to the function,
wherein the initial set of one or more coefficients is adjusted in order to minimize the function,
wherein the function is a hyperbolic sine-based function.

2. The method according to 1, wherein the function is a second order hyperbolic sine-based function.

3. The method according to 1, wherein the function is a fourth order hyperbolic sine-based function.

4. The method according to 1, wherein the function is defined as
$$J ( k ) = \frac{1}{A} sinh ( {Ae}^{2} ( k ) ) ,$$
where J is a value of the function, k is a time value, A is a tuning parameter, and e is the error signal.

5. The method according to 1, wherein the function is defined as
$$J ( k ) = \frac{1}{4 A} sinh ( {Ae}^{2} ( k ) ) ,$$
where J is a value of the function, k is a time value, A is a tuning parameter, and e is the error signal.

6. The method according to 1, wherein a stochastic gradient of the function comprises a time-varying step-size.

7. The method according to 6, wherein the stochastic gradient of the function further comprises an upper bound step-size and a lower bound step-size.

8. The method according to 6, wherein the stochastic gradient of the function further comprises a generic upper bound step-size.

9. The method according to 8, wherein the generic upper bound step-size is defined as
$${μ}_{m ax} = \frac{1}{Tr \{ {R}_{x} \} + ϵ} \cdot \frac{1}{1 + {e}^{2} \cdot ( k )} ,$$
where Tr is a trace operator, Rₓ is an auto-correlation matrix of the input signal, ϵ is a non-zero constant, k is a time value, and e is the error signal.

10. The method according to 8, wherein the generic upper bound step-size is defined as
$${μ}_{m ax} = \frac{1}{Tr \{ {R}_{x} \} + ϵ} ,$$
where Tr is a trace operator, Rₓ is an auto-correlation matrix of the input signal, and ϵ is a non-zero constant.

11. A device for adaptive filtering, comprising a processing circuitry configured to:
receive an input signal;
generate an initial output signal based upon an initial set of one or more coefficients;
determine an error signal based upon the difference between the initial output signal and a desired response signal;
calculate a solution to a function based upon the error signal; and
generate a subsequent output signal based upon a subsequent set of one or more coefficients,
wherein the subsequent set of one or more coefficients is determined by adjusting the initial set of one or more coefficients based upon the calculation of the solution to the function,
wherein the initial set of one or more coefficients is adjusted in order to minimize the function,
wherein the function is a hyperbolic sine-based function.

12. The device according to 11, wherein the function is a second order hyperbolic sine-based function, a fourth order hyperbolic sine-based function, or a combination thereof.

13. The device according to 11, wherein the function is defined as
$$J ( k ) = \frac{1}{A} sinh ( {Ae}^{2} ( k ) ) ,$$
where J is a value of the function, k is a time value, A is a tuning parameter, and e is the error signal.

14. The device according to 11, wherein the function is defined as
$$J ( k ) = \frac{1}{4 A} sinh ( {Ae}^{2} ( k ) ) ,$$
where J is a value of the function, k is a time value, A is a tuning parameter, and e is the error signal.

15. The device according to 11, wherein a stochastic gradient of the function comprises a time-varying step-size.

16. The device according to 15, wherein the stochastic gradient of the function further comprises an upper bound step-size and a lower bound step-size.

17. The device according to 15, wherein the stochastic gradient of the function further comprises a generic upper bound step-size.

18. The device according to 17, wherein the generic upper bound step-size is defined as
$${μ}_{m ax} = \frac{1}{Tr \{ {R}_{x} \} + ϵ} \cdot \frac{1}{1 + {e}^{2} \cdot ( k )} ,$$
where Tr is a trace operator, Rₓ is an auto-correlation matrix of the input signal, ϵ is a non-zero constant, k is a time value, and e is the error signal.

19. The device according to 17, wherein the generic upper bound step-size is defined as
$${μ}_{m ax} = \frac{1}{Tr \{ {R}_{x} \} + ϵ} ,$$
where Tr is a trace operator, Rₓ is an auto-correlation matrix of the input signal, and ϵ is a non-zero constant.

20. A non-transitory computer-readable medium comprising a set of instructions, which, when executed by a processing circuitry, cause the processing circuitry to perform a method for adaptive filtering, comprising:
receiving, via processing circuitry, an input signal;
generating, via the processing circuitry, an initial output signal based upon an initial set of one or more coefficients;
determining, via the processing circuitry, an error signal based upon the difference between the initial output signal and a desired response signal;
calculating, via the processing circuitry, a solution to a function based upon the error signal; and
generating, via the processing circuitry, a subsequent output signal based upon a subsequent set of one or more coefficients,
wherein the subsequent set of one or more coefficients is determined by adjusting the initial set of one or more coefficients based upon the calculation of the solution to the function,
wherein the initial set of one or more coefficients is adjusted in order to minimize the function,
wherein the function is a hyperbolic sine-based function.
